(19) United States
(12) Patent Application Publication
(10) Pub. No.: US 2025/0210592 A1
(43) Pub. Date: Jun. 26, 2025

(54) SEMICONDUCTOR DEVICE

(71) Applicant: Kioxia Corporation, Tokyo (JP)

(72) Inventors: Yasuo TAKEMOTO, Kamakura Kanagawa (JP); Masayuki MIURA, Ota Tokyo (JP)

(73) Assignee: Kioxia Corporation, Tokyo (JP)

(21) Appl. No.: 18/809,433

(22) Filed: Aug. 20, 2024

(30) Foreign Application Priority Data
Dec. 20, 2023 (JP) 2023-214976

(51) Int. Cl. H01L 25/065; H01L 23/00; H01L 23/498

(52) U.S. Cl. CPC H01L 25/0657; H01L 23/49838; H01L 24/48; H01L 2224/48145; H01L 2224/48227; H01L 2225/06506; H01L 2225/0651; H01L 2225/06562; H01L 2924/3512

(57) ABSTRACT

In one embodiment, a semiconductor device includes a substrate, one or more first substrate pads provided on the substrate, and one or more first chips provided on the substrate and located in a first direction from the first substrate pads, each of the first chips including one or more first chip pads electrically connected to the first substrate pads. The device further includes one or more second substrate pads provided on the substrate, and one or more second chips provided on the first chips and located in a second direction from the second substrate pads, the second direction intersecting the first direction, each of the second chips including one or more second chip pads electrically connected to the second substrate pads. Moreover, each of the second chip pads is located to overlap with a highest first chip of the first chips in planar view.

### CROSS-REFERENCE TO RELATED APPLICATION

This application is based upon and claims the benefit of priority from the prior Japanese Patent Application No. 2023-214976, filed on Dec. 20, 2023, the entire contents of which are incorporated herein by reference.

### FIELD

Embodiments described herein relate to a semiconductor device.

### BACKGROUND

When a semiconductor device is manufactured by stacking semiconductor chips, various problems may occur due to the stacking of the semiconductor chips. For example, wire bonding to the semiconductor chips may be difficult.

### BRIEF DESCRIPTION OF THE DRAWINGS

FIG. 1 is a cross-sectional view illustrating the structure of a semiconductor device of a first embodiment;

FIG. 2 is a plan view illustrating the structure of the semiconductor device of the first embodiment;

FIGS. 3 to 5 are plan views illustrating a method of manufacturing the semiconductor device of the first embodiment;

FIG. 6 is a cross-sectional view illustrating the structure of a semiconductor device of a comparative example of the first embodiment;

FIG. 7 is a plan view illustrating the structure of the semiconductor device of the comparative example of the first embodiment;

FIGS. 8 to 10 are plan views illustrating a method of manufacturing the semiconductor device of the comparative example of the first embodiment;

FIG. 11 is a cross-sectional view for describing the structure of the semiconductor device of the first embodiment;

FIG. 12 is a plan view for describing the structure of the semiconductor device of the first embodiment;

FIG. 13 is a cross-sectional view illustrating the structure of a semiconductor device of a second embodiment;

FIG. 14 is a plan view illustrating the structure of the semiconductor device of the second embodiment;

FIGS. 15 to 17 are plan views illustrating a method of manufacturing the semiconductor device of the second embodiment;

FIG. 18 is a cross-sectional view illustrating the structure of a semiconductor device of a third embodiment;

FIG. 19 is a plan view illustrating the structure of the semiconductor device of the third embodiment;

FIGS. 20 to 22 are plan views illustrating a method of manufacturing the semiconductor device of the third embodiment;

FIG. 23 is a cross-sectional view illustrating the structure of a semiconductor device of a fourth embodiment;

FIG. 24 is a plan view illustrating the structure of the semiconductor device of the fourth embodiment;

FIGS. 25 to 27 are plan views illustrating a method of manufacturing the semiconductor device of the fourth embodiment;

FIG. 28 is a cross-sectional view illustrating the structure of a semiconductor device of a first variant example of the fourth embodiment;

FIG. 29 is a plan view illustrating the structure of the semiconductor device of the first variant example of the fourth embodiment;

FIG. 30 is a plan view illustrating the structure of a semiconductor device of a second variant example of the fourth embodiment;

FIG. 31 is a cross-sectional view illustrating the structure of a semiconductor device of a variant example of the first embodiment;

FIG. 32 is a plan view illustrating the structure of the semiconductor device of the variant example of the first embodiment; and

FIGS. 33 to 35 are plan views illustrating a method of manufacturing the semiconductor device of the variant example of the first embodiment.

### DETAILED DESCRIPTION

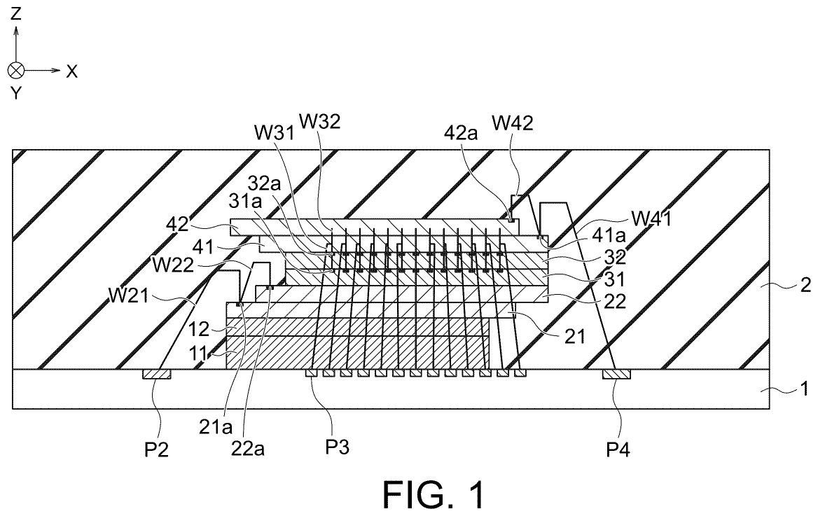

Embodiments will now be explained with reference to the accompanying drawings. In FIGS. 1 to 35, identical configurations are marked with the same symbol and redundant explanations are omitted.

In one embodiment, a semiconductor device includes a substrate, one or more first substrate pads provided on the substrate, and one or more first chips provided on the substrate and located in a first direction from the first substrate pads, each of the first chips including one or more first chip pads electrically connected to the first substrate pads. The device further includes one or more second substrate pads provided on the substrate, and one or more second chips provided on the first chips and located in a second direction from the second substrate pads, the second direction intersecting the first direction, each of the second chips including one or more second chip pads electrically connected to the second substrate pads. Moreover, each of the second chip pads is located to overlap with a highest first chip of the first chips in planar view.

### First Embodiment

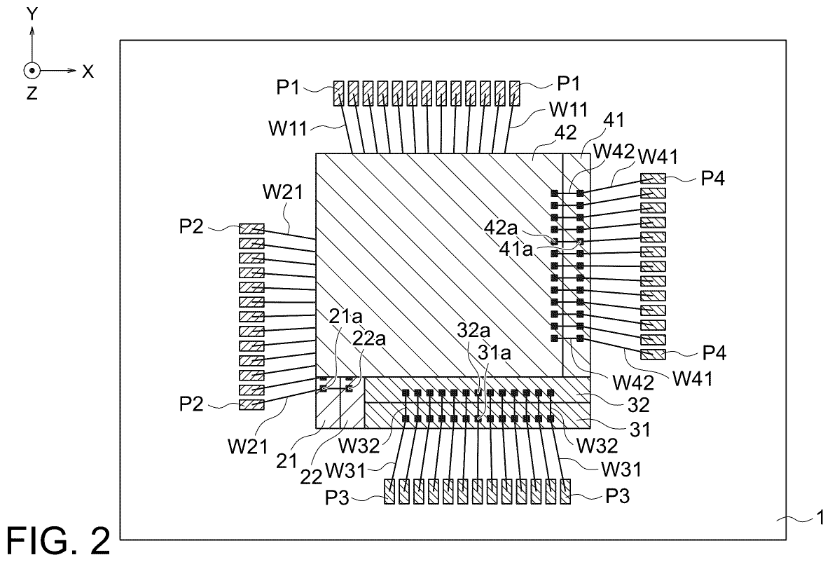

FIGS. 1 and 2 are a cross-sectional view and a plan view, respectively, illustrating the structure of a semiconductor device of the first embodiment.

The semiconductor device of the present embodiment includes a substrate 1, a resin layer 2, a plurality of metal pads P1, a plurality of metal pads P2, a plurality of metal pads P3, and a plurality of metal pads P4. The metal pads P1 are an example of the one or more first substrate pads. The metal pads P2 are an example of the one or more second substrate pads. The metal pads P3 are an example of one or more third substrate pads. The metal pads P4 are an example of one or more fourth substrate pads.

The semiconductor device of the present embodiment further includes a plurality of semiconductor chips 11-12 electrically connected to the metal pads P1, a plurality of semiconductor chips 21-22 electrically connected to the metal pads P2, a plurality of semiconductor chips 31-32 electrically connected to the metal pads P3, and a plurality of semiconductor chips 41-42 electrically connected to the metal pads P4. These semiconductor chips 11-42 are, for example, semiconductor memory chips. The semiconductor chips 11-12 are an example of the one or more first chips. The semiconductor chips 21-22 are an example of the one or more second chips. The semiconductor chips 31-32 are an example of one or more third chips. The semiconductor chips 41-42 are an example of one or more fourth chips.

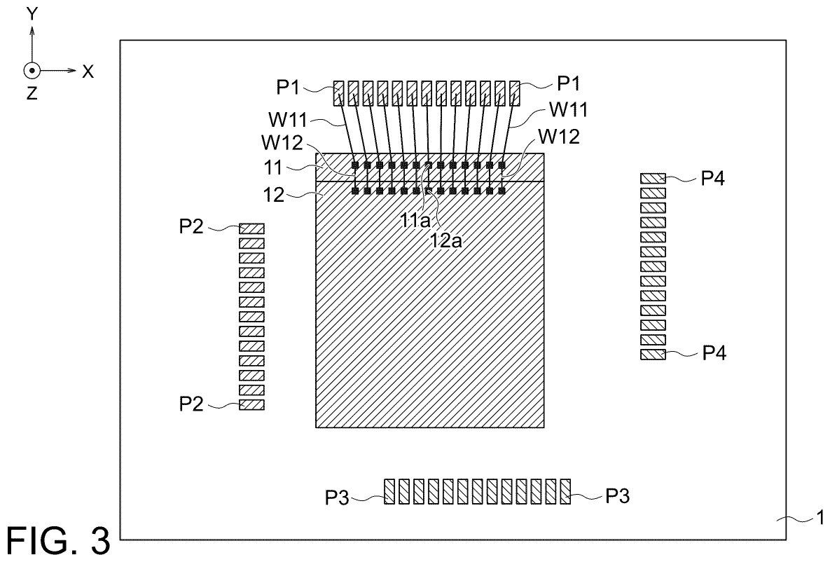

FIGS. 1 and 2 show X, Y, and Z directions intersecting each other. In FIGS. 1 and 2, the X and Y directions are parallel to the surface of the substrate 1, and the Z-direction is perpendicular to the surface of the substrate 1. The X, Y, and Z directions are, therefore, perpendicular to each other. In this specification, viewing the semiconductor device in the −Z direction from a +Z position relative to the semiconductor device, as shown in FIG. 2, is treated as planar view. This applies equally to FIGS. 3 to 35. In the present embodiment, the −Y direction is an example of a first direction, the +X direction is an example of a second direction, the +Y direction is an example of a third direction, and the −X direction is an example of a fourth direction.

The resin layer 2 is formed on the substrate 1 to cover the metal pads P1-P4 and the semiconductor chips 11-42. The resin layer 2 is omitted in FIG. 2. Further details of the metal pads P1-P4 and the semiconductor chips 11-42 are described later.

FIGS. 3 to 5 are plan views illustrating a method of manufacturing the semiconductor device of the first embodiment.

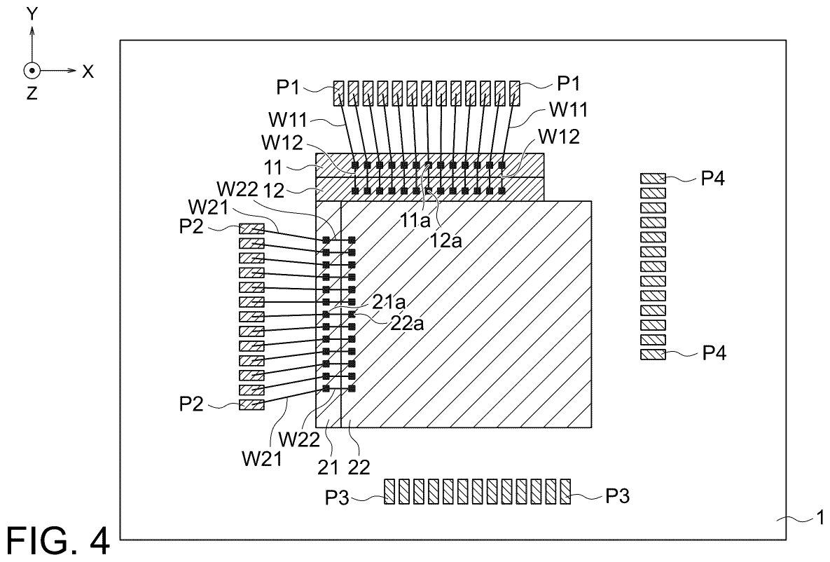

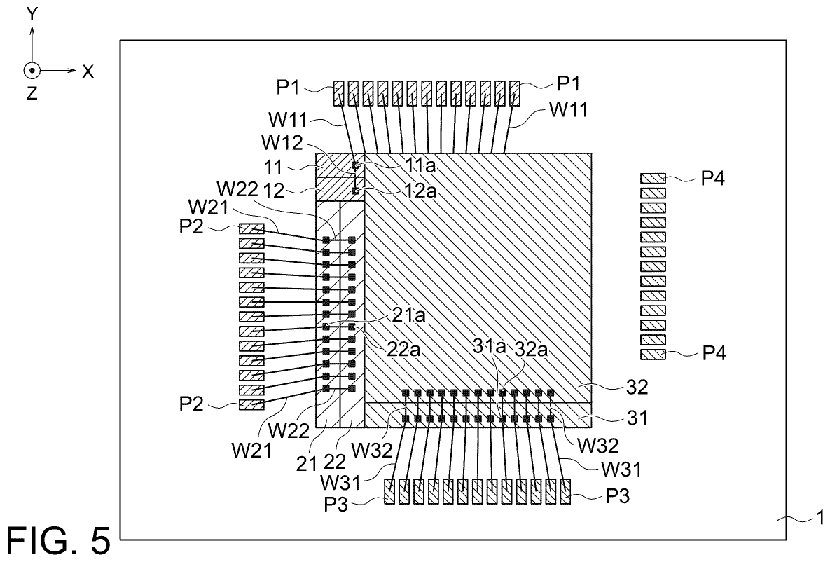

The semiconductor device of the present embodiment is manufactured by stacking the semiconductor chips 11-42 on the substrate 1 in sequence. First, the metal pads P1-P4 are formed on the top surface of the substrate 1, and the semiconductor chips 11-12 are stacked in sequence on the substrate 1 (FIG. 3). Next, the semiconductor chips 21-22 are stacked in sequence on the semiconductor chip 12 (FIG. 4). Then, the semiconductor chips 31-32 are stacked in sequence on the semiconductor chip 22 (FIG. 5). After that, the semiconductor chips 41-42 are stacked in sequence on the semiconductor chip 32, and the resin layer 2 is formed on the substrate 1 (FIGS. 1 and 2). For example, the substrate 1 and the semiconductor chip 11 are bonded to each other via an adhesive layer, and the semiconductor chips 11-42 are also bonded to each other via adhesive layers.

In the following, the structure of the semiconductor device of the present embodiment will be described with reference to FIGS. 1 and 2. In this description, FIGS. 3 to 5 will also be referenced as appropriate. This is because some components of the semiconductor device of the present embodiment illustrated in FIGS. 3 to 5 are hidden by other components and thus not shown in FIGS. 1 and 2.

### [Metal Pads P1-P4]

The metal pads P1-P4 are arranged around the semiconductor chips 11-42 on the substrate 1, as shown in FIG. 2. Specifically, the metal pads P1 are located in the +Y direction from the semiconductor chips 11-42 and are arranged in line along the X direction. The metal pads P2 are located in the −X direction from the semiconductor chips 11-42 and are arranged in line along the Y direction. The metal pads P3 are located in the −Y direction from the semiconductor chips 11-42 and are arranged in line along the X direction. The metal pads P4 are located in the +X direction from the semiconductor chips 11-42 and are arranged in line along the Y direction.

In the present embodiment, the semiconductor chips 11-42 have congruent shapes in planar view. Specifically, the shapes of the semiconductor chips 11-42 are congruent rectangles in planar view. The semiconductor chips 11-42 in the present embodiment have the same thickness, except for the semiconductor chip 11 (FIG. 1). In the present embodiment, the thickness of the lowest semiconductor chip 11 of the semiconductor chips 11-42 is thicker than the thicknesses of the other semiconductor chips 12-42. In the present embodiment, the thicknesses of the semiconductor chips 12-42 are set to 50 μm or less (e.g., 20-50 μm). Furthermore, in the present embodiment, the thickness of the semiconductor chip 11 may also be set to 50 μm or less (e.g., 20-50 μm). Note that the shapes and thicknesses of the semiconductor chips 11-42 may be different from those in the present embodiment.

### [Semiconductor Chips 11-12]

The semiconductor chips 11-12 are located in the −Y direction from the metal pads P1 and are electrically connected to the metal pads P1 (FIG. 3). The (rectangular) top surfaces of the semiconductor chips 11-12 have short sides parallel to the X direction and long sides parallel to the Y direction. The semiconductor chip 12 is located on the semiconductor chip 11, not at a position where it completely overlaps with the semiconductor chip 11, but at a position where it partially overlaps with the semiconductor chip 11 in planar view. Specifically, the center of gravity of the top surface of the semiconductor chip 12 is located in the −Y direction from the center of gravity of the top surface of the semiconductor chip 11. Thus, the semiconductor chips 11-12 are stacked on the substrate 1 to form stairsteps in the −Y direction.

The semiconductor chip 11 has a plurality of metal pads 11a provided on the top surface of the semiconductor chip 11 (FIG. 3). The metal pads 11a are located in the stairstep portion of the semiconductor chip 11, i.e., near the short side of the semiconductor chip 11 in the +Y direction, and are arranged in line along the X direction. These metal pads 11a are electrically connected to the metal pads P1 by a plurality of bonding wires W11. These metal pads 11a are located at a position where they do not overlap with the semiconductor chip 12 in planar view. The metal pads 11a are an example of one or more first chip pads. For example, the bonding wires W11 are bonded to the metal pad 11a by solder and to the metal pads P1 by solder (the same applies to the other bonding pads).

The semiconductor chip 12 has a plurality of metal pads 12a provided on the top surface of the semiconductor chip 12 (FIG. 3). The metal pads 12a are located in the stairstep portion of the semiconductor chip 12, i.e., near the short side of the semiconductor chip 12 in the +Y direction, and are arranged in line along the X direction. These metal pads 12a are electrically connected to the metal pads 11a by a plurality of bonding wires W12 so that the metal pads 12a are electrically connected to the metal pads P1. These metal pads 12a are located in the −Y direction from the above plurality of metal pads 11a. The metal pads 12a are another example of the one or more first chip pads.

### [Semiconductor Chips 21-22]

The semiconductor chips 21-22 are located in the +X direction from the metal pads P2 and are electrically connected to the metal pads P2 (FIG. 4). The (rectangular) top surfaces of the semiconductor chips 21-22 have short sides parallel to the Y direction and long sides parallel to the X direction. The semiconductor chip 22 is located on the semiconductor chip 21, not at a position where it completely overlaps with the semiconductor chip 21, but at a position where it partially overlaps with the semiconductor chip 21 in planar view. Specifically, the center of gravity of the top surface of the semiconductor chip 22 is located in the +X direction from the center of gravity of the top surface of the semiconductor chip 21. Thus, the semiconductor chips 21-22 are stacked on the semiconductor chip 12 to form stairsteps in the +X direction.

The semiconductor chip 21 has a plurality of metal pads 21a provided on the top surface of the semiconductor chip 21 (FIG. 4). The metal pads 21a are located in the stairstep portion of the semiconductor chip 21, i.e., near the short side of the semiconductor chip 21 in the −X direction, and are arranged in line along the Y direction. These metal pads 21a are electrically connected to the metal pads P2 by a plurality of bonding wires W21. These metal pads 21a are located at a position where they do not overlap with the semiconductor chip 22 in planar view. The metal pads 21a are an example of one or more second chip pads.

The semiconductor chip 22 has a plurality of metal pads 22a provided on the top surface of the semiconductor chip 22 (FIG. 4). The metal pads 22a are located in the stairstep portion of the semiconductor chip 22, i.e., near the short side of the semiconductor chip 22 in the −X direction, and are arranged in line along the Y direction. These metal pads 22a are electrically connected to the metal pads 21a by a plurality of bonding wires W22 so that the metal pads 22a are electrically connected to the metal pads P2. These metal pads 22a are located in the +X direction from the above plurality of metal pads 21a. The metal pads 22a are another example of the one or more second chip pads.

In the present embodiment, the semiconductor chips 11-12 are arranged so that their short sides are parallel to the X direction and their long sides are parallel to the Y direction, forming stairsteps extending in the −Y direction. In contrast, the semiconductor chips 21-22 are arranged so that their short sides are parallel to the Y direction and their long sides are parallel to the X direction, forming stairsteps extending in the +X direction that intersects the −Y direction. As a result, these four semiconductor chips 11-22 as a whole form an L-shape in planar view. The semiconductor chip 21 in the present embodiment is located on the semiconductor chip 12 so that the lower left corner of the semiconductor chip 21 overlaps with the lower left corner of the semiconductor chip 12 in planar view. (The term “lower left” here means lower left on the page. The same applies hereinafter.) Note that the lower left corner of the semiconductor chip 21 may not overlap with the lower left corner of the semiconductor chip 12, for example, the lower left corner of the semiconductor chip 21 may be located in the −Y direction from the lower left corner of the semiconductor chip 12.

In the present embodiment, the short side of the semiconductor chip 21 in the −X direction overlaps with the long side of the semiconductor chip 11 in the −X direction and the long side of the semiconductor chip 12 in the −X direction in planar view. Furthermore, in the present embodiment, the short side of the semiconductor chip 12 in the −Y direction overlaps with the long side of the semiconductor chip 21 in the −Y direction and the long side of the semiconductor chip 22 in the −Y direction in planar view.

Each of the metal pads 21a-22a in the present embodiment is located at a position where it overlaps with the highest semiconductor chip 12 of the semiconductor chips 11-12 in planar view. In other words, the metal pads 21a-22a in the present embodiment are located so as not to be outside the top surface of the semiconductor chip 12 in planar view. In the present embodiment, therefore, the semiconductor chip 12 is present in the −Z direction from the metal pads 21a-22a. The present embodiment makes it possible to reduce the possibility of cracking of the semiconductor chips 21-22 even when the semiconductor chips 21-22 are thin by virtue of the presence of the semiconductor chip 12 in the −Z direction from the metal pads 21a-22a. FIG. 1 shows the metal pads 21a-22a located at a position where they overlap with the semiconductor chip 12 in planar view.

### [Semiconductor Chips 31-32]

The semiconductor chips 31-32 are located in the +Y direction from the metal pads P3 and are electrically connected to the metal pads P3 (FIG. 5). The (rectangular) top surfaces of the semiconductor chips 31-32 have short sides parallel to the X direction and long sides parallel to the Y direction. The semiconductor chip 32 is located on the semiconductor chip 31, not at a position where it completely overlaps with the semiconductor chip 31, but at a position where it partially overlaps with the semiconductor chip 31 in planar view. Specifically, the center of gravity of the top surface of the semiconductor chip 32 is located in the +Y direction from the center of gravity of the top surface of the semiconductor chip 31. Thus, the semiconductor chips 31-32 are stacked on the semiconductor chip 22 to form stairsteps in the +Y direction.

The semiconductor chip 31 has a plurality of metal pads 31a provided on the top surface of the semiconductor chip 31 (FIG. 5). The metal pads 31a are located in the stairstep portion of the semiconductor chip 31, i.e., near the short side of the semiconductor chip 31 in the −Y direction, and are arranged in line along the X direction. These metal pads 31a are electrically connected to the metal pads P3 by a plurality of bonding wires W31. These metal pads 31a are located at a position where they do not overlap with the semiconductor chip 32 in planar view. The metal pads 31a are an example of one or more third chip pads.

The semiconductor chip 32 has a plurality of metal pads 32a provided on the top surface of the semiconductor chip 32 (FIG. 5). The metal pads 32a are located in the stairstep portion of the semiconductor chip 32, i.e., near the short side of the semiconductor chip 32 in the −Y direction, and are arranged in line along the X direction. These metal pads 32a are electrically connected to the metal pads 31a by a plurality of bonding wires W32 so that the metal pads 32a are electrically connected to the metal pads P3. These metal pads 32a are located in the +Y direction from the above plurality of metal pads 31a. The metal pads 32a are another example of the one or more third chip pads.

In the present embodiment, the semiconductor chips 21-22 are arranged so that their short sides are parallel to the Y direction and their long sides are parallel to the X direction, forming stairsteps extending in the +X direction. In contrast, the semiconductor chips 31-32 are arranged so that their short sides are parallel to the X direction and their long sides are parallel to the Y direction, forming stairsteps extending in the +Y direction that intersects the +X direction. As a result, these four semiconductor chips 21-32 as a whole form an L-shape in planar view. The semiconductor chip 31 in the present embodiment is located on the semiconductor chip 22 so that the lower right corner of the semiconductor chip 31 overlaps with the lower right corner of the semiconductor chip 22 in planar view. (The term “lower right” here means lower right on the page. The same applies hereinafter.) Note that the lower right corner of the semiconductor chip 31 may not overlap with the lower right corner of the semiconductor chip 22, for example, the lower right corner of the semiconductor chip 31 may be located in the +X direction from the lower right corner of the semiconductor chip 22.

In the present embodiment, the short side of the semiconductor chip 31 in the −Y direction overlaps with the long side of the semiconductor chip 21 in the −Y direction and the long side of the semiconductor chip 22 in the −Y direction in planar view. Furthermore, in the present embodiment, the short side of the semiconductor chip 22 in the +X direction overlaps with the long side of the semiconductor chip 31 in the +X direction and the long side of the semiconductor chip 32 in the +X direction in planar view.

Each of the metal pads 31a-32a in the present embodiment is located at a position where it overlaps with the highest semiconductor chip 22 of the semiconductor chips 21-22 in planar view. In other words, the metal pads 31a-32a in the present embodiment are located so as not to be outside the top surface of the semiconductor chip 22 in planar view. In the present embodiment, therefore, the semiconductor chip 22 is present in the −Z direction from the metal pads 31a-32a. The present embodiment makes it possible to reduce the possibility of cracking of the semiconductor chips 31-32 even when the semiconductor chips 31-32 are thin by virtue of the presence of the semiconductor chip 22 in the −Z direction from the metal pads 31a-32a. FIG. 1 shows the metal pads 31a-32a located at a position where they overlap with the semiconductor chip 22 in planar view.

### [Semiconductor Chips 41-42]

The semiconductor chips 41-42 are located in the −X direction from the metal pads P4 and are electrically connected to the metal pads P4 (FIG. 2). The (rectangular) top surfaces of the semiconductor chips 41-42 have short sides parallel to the Y direction and long sides parallel to the X direction. The semiconductor chip 42 is located on the semiconductor chip 41, not at a position where it completely overlaps with the semiconductor chip 41, but at a position where it partially overlaps with the semiconductor chip 41 in planar view. Specifically, the center of gravity of the top surface of the semiconductor chip 42 is located in the −X direction from the center of gravity of the top surface of the semiconductor chip 41. Thus, the semiconductor chips 41-42 are stacked on the semiconductor chip 32 to form stairsteps in the −X direction.

The semiconductor chip 41 has a plurality of metal pads 41a provided on the top surface of the semiconductor chip 41 (FIG. 2). The metal pads 41a are located in the stairstep portion of the semiconductor chip 41, i.e., near the short side of the semiconductor chip 41 in the +X direction, and are arranged in line along the Y direction. These metal pads 41a are electrically connected to the metal pads P4 by a plurality of bonding wires W41. These metal pads 41a are located at a position where they do not overlap with the semiconductor chip 42 in planar view. The metal pads 41a are an example of one or more fourth chip pads.

The semiconductor chip 42 has a plurality of metal pads 42a provided on the top surface of the semiconductor chip 42 (FIG. 2). The metal pads 42a are located in the stairstep portion of the semiconductor chip 42, i.e., near the short side of the semiconductor chip 42 in the +X direction, and are arranged in line along the Y direction. These metal pads 42a are electrically connected to the metal pads 41a by a plurality of bonding wires W42 so that the metal pads 42a are electrically connected to the metal pads P4. These metal pads 42a are located in the −X direction from the above plurality of metal pads 41a. The metal pads 42a are another example of the one or more fourth chip pads.

In the present embodiment, the semiconductor chips 31-32 are arranged so that their short sides are parallel to the X direction and their long sides are parallel to the Y direction, forming stairsteps extending in the +Y direction. In contrast, the semiconductor chips 41-42 are arranged so that their short sides are parallel to the Y direction and their long sides are parallel to the X direction, forming stairsteps extending in the −X direction that intersects the +Y direction. As a result, these four semiconductor chips 31-42 as a whole form an L-shape in planar view. The semiconductor chip 41 in the present embodiment is located on the semiconductor chip 32 so that the upper right corner of the semiconductor chip 41 overlaps with the upper right corner of the semiconductor chip 32 in planar view. (The term “upper right” here means upper right on the page. The same applies hereinafter.) Note that the upper right corner of the semiconductor chip 41 may not overlap with the upper right corner of the semiconductor chip 32, for example, the upper right corner of the semiconductor chip 41 may be located in the +Y direction from the upper right corner of the semiconductor chip 32.

In the present embodiment, the short side of the semiconductor chip 41 in the +X direction overlaps with the long side of the semiconductor chip 31 in the +X direction and the long side of the semiconductor chip 32 in the +X direction in planar view. Furthermore, in the present embodiment, the short side of the semiconductor chip 32 in +Y direction overlaps with the long side of the semiconductor chip 41 in the +Y direction and the long side of the semiconductor chip 42 in the +Y direction in planar view.

Each of the metal pads 41a-42a in the present embodiment is located at a position where it overlaps with the highest semiconductor chip 32 of the semiconductor chips 31-32 in planar view. In other words, the metal pads 41a-42a in the present embodiment are located so as not to be outside the top surface of the semiconductor chip 32 in planar view. In the present embodiment, therefore, the semiconductor chip 32 is present in the −Z direction from the metal pads 41a-42a. The present embodiment makes it possible to reduce the possibility of cracking of the semiconductor chips 41-42 even when the semiconductor chips 41-42 are thin by virtue of the presence of the semiconductor chip 32 in the −Z direction from the metal pads 41a-42a. FIG. 1 shows the metal pads 41a-42a located at a position where they overlap with the semiconductor chip 32 in planar view.

As described above, the semiconductor chips 11-12 form stairsteps extending in the −Y direction, and the semiconductor chips 21-22 form stairsteps extending in the +X direction. Therefore, the direction in which the stairsteps of the semiconductor chips 21-22 extend (+X direction) is rotated 90 degrees counterclockwise with respect to the direction in which the stairsteps of the semiconductor chips 11-12 extend (−Y direction) in planar view. Similarly, the direction in which the stairsteps of the semiconductor chips 31-32 extend (+Y direction) is rotated 90 degrees counterclockwise with respect to the direction in which the stairsteps of the semiconductor chips 21-22 extend (+X direction) in planar view. Likewise, the direction in which the stairsteps of the semiconductor chips 41-42 extend (−X direction) is rotated 90 degrees counterclockwise with respect to the direction in which the stairsteps of the semiconductor chips 31-32 extend (+Y direction) in planar view. In this way, these semiconductor chips 11-42 are arranged in a spiral extending in the Z direction. Specifically, the positional relationship of these semiconductor chips 11-42 looks like a spiral staircase, rotating and rising in the +Z direction. Counterclockwise rotation is an example of a predetermined rotational direction.

The spiral (helical) arrangement of the semiconductor chips 11-42 is now explained. When the centers of gravity of the semiconductor chips 11-42 are connected by a line in the order of the semiconductor chips 11-42, this line is a spiral line extending in the +Z direction. Although a spiral line generally refers to a line that is circular in planar view, the term “spiral line” as used herein may include not only a line that is circular in planar view, but also a line that forms a shape other than a circle in planar view. For example, when the centers of gravity of the semiconductor chips 11-42 are connected by a line in the order of the semiconductor chips 11-42, the shape formed by this line is roughly quadrilateral (tetragon) in planar view. This is because, in planar view, the center of gravity of the semiconductor chip 12 is located in the −Y direction from the center of gravity of the semiconductor chip 11, the center of gravity of the semiconductor chip 22 is located in the +X direction from the center of gravity of the semiconductor chip 21, the center of gravity of the semiconductor chip 32 is located in the +Y direction of the center of gravity from the semiconductor chip 31, and the center of gravity of the semiconductor chip 42 is located in the −X direction from the center of gravity of the semiconductor chip 41.

Here, the semiconductor chips 11-42 make just one revolution (360 degrees) counterclockwise in planar view. In this case, if the center of gravity of the semiconductor chip 42 coincides with the center of gravity of the semiconductor chip 11 in planar view, the line connecting the centers of gravity of the semiconductor chips 11-42 forms a quadrilateral, that is, the line is a closed line in planar view. However, in the present embodiment, the center of gravity of the semiconductor chip 42 does not coincide with the center of gravity of the semiconductor chip 11 in planar view, so the line connecting the centers of gravity of the semiconductor chips 11-42 is an open line rather than a closed line. Specifically, the line connecting the centers of gravity of the semiconductor chips 11-42 in the present embodiment is a line corresponding to a part of a quadrilateral.

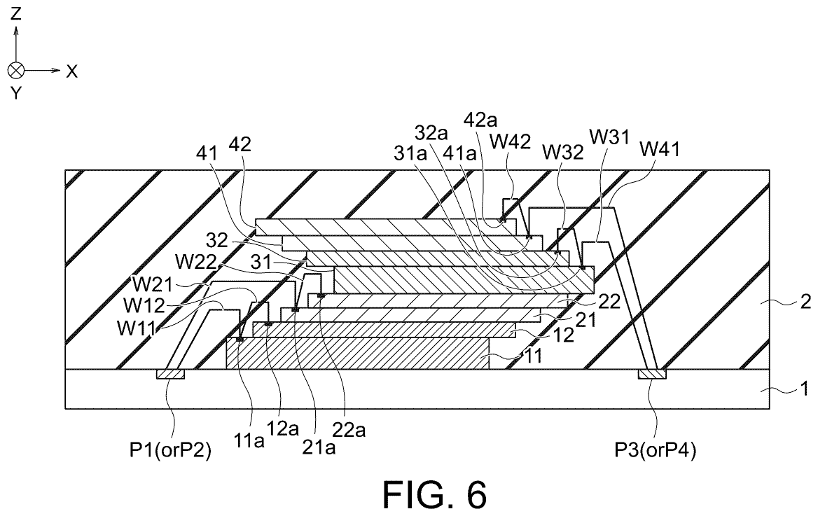

If the semiconductor chips 11-42 make two or more revolutions in planar view, a large number of metal pads P1, a large number of metal pads P2, a large number of metal pads P3, and a large number of metal pads P4 have to be arranged in the +Y, −X, −Y, and +X directions of the semiconductor chips 11-42, respectively. This creates the same problems as in the comparative example described below (FIGS. 6 to 10). In contrast, the semiconductor chips 11-42 in the present embodiment make just one revolution in planar view. This makes it possible to mitigate the problems in the comparative example. This applies equally to each embodiment described later.

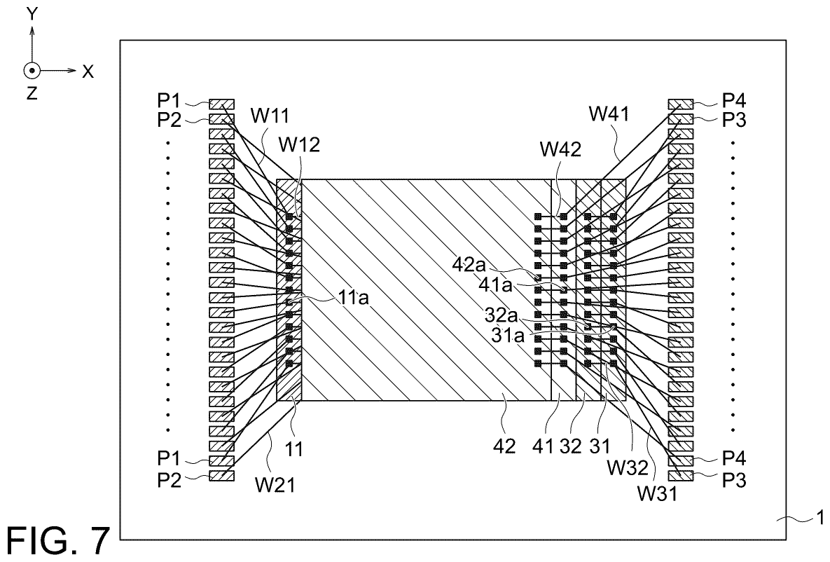

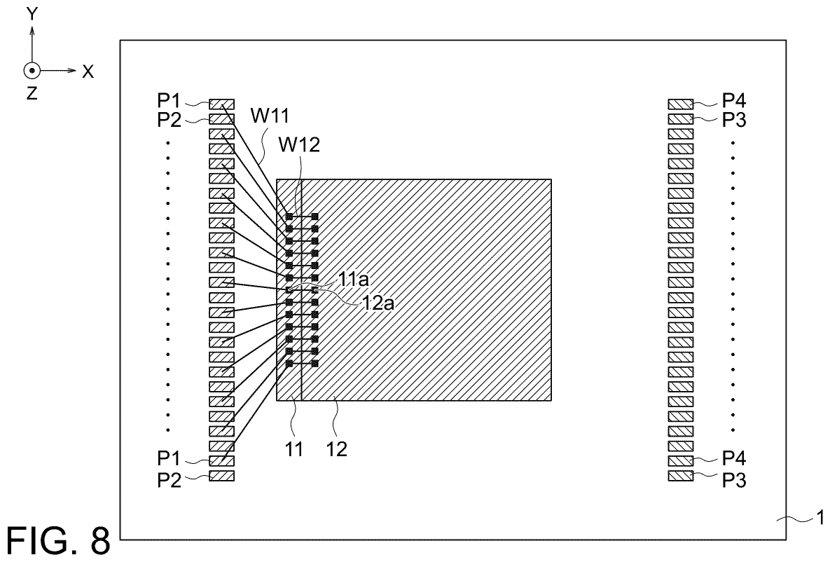

FIGS. 6 and 7 are a cross-sectional view and a plan view, respectively, illustrating the structure of a semiconductor device of the comparative example of the first embodiment. FIGS. 8 to 10 are plan views illustrating a method of manufacturing the semiconductor device of the comparative example of the first embodiment. FIGS. 6 to 10 correspond to FIGS. 1 to 5, respectively.

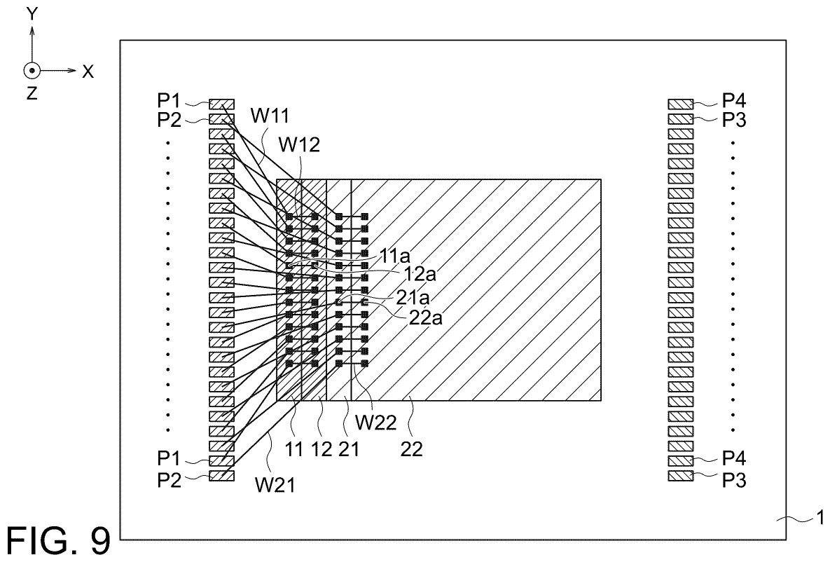

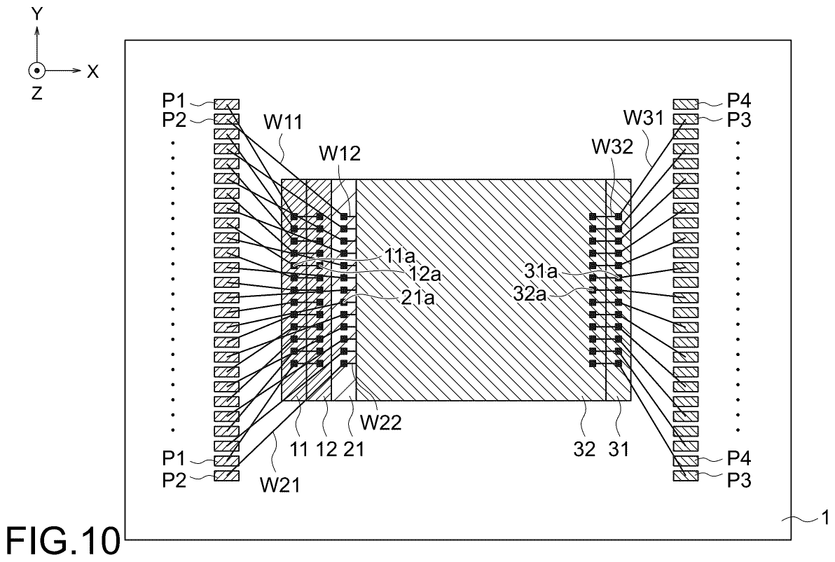

The components of the semiconductor device of the comparative example (FIGS. 6 to 10) are the same as the components of the semiconductor device in the present embodiment (FIGS. 1 to 5). However, in the comparative example, the metal pads P1-P2 are arranged alternately in the −X direction from the semiconductor chips 11-42, and the metal pads P3-P4 are arranged alternately in the +X direction from the semiconductor chips 11-42. In addition, in the comparative example, the semiconductor chips 11-22 form stairsteps extending in the +X direction (FIGS. 8 and 9), and the semiconductor chips 31-42 form stairsteps extending in the −X direction (FIGS. 10 and 7).

In the following, a comparison is made between the present embodiment and the comparative example.

In the comparative example, the metal pads P1-P2 for two channels are arranged in line in the −X direction from the semiconductor chips 11-42 (FIG. 7). Consequently, the length of the bonding wire W11 for the metal pad P1 at the end of the line in +Y direction and the length of the bonding wire W21 for the metal pad P2 at the end of the line in the −Y direction are longer. This is undesirable in terms of resistance and impedance of the bonding wires W11 and W21. This applies equally to the metal pads P3-P4.

In the comparative example, the metal pads 31a of the semiconductor chip 31 are located near the line of the metal pads P3-P4 in planar view (FIG. 7). This is because the stairsteps of the semiconductor chips 11-42 extend only in the +X direction and thus the dimensions of a shape formed by the semiconductor chips 11-42 as a whole tend to be longer in the X direction in planar view. In FIG. 6, therefore, the angle of a bonding wire W31 with respect to the top surface of the substrate 1 is large. Specifically, since the angle depends on the ratio B/A between the distance “A” in the XY plane and the distance “B” in the Z direction between the metal pad P3 and the metal pad 31a electrically connected to this bonding wire W31, if the metal pad 31a is nearer to the metal pad P3 in planar view, the ratio B/A becomes larger and thus the angle becomes larger. This makes it difficult to bond the bonding wire W31 to the metal pad 31a. This applies equally to the other bonding wires W11, W21, and W41.

In the comparative example, the semiconductor chip 22 is not present in the −Z direction from the metal pads 31a (FIG. 6). This is because the semiconductor chip 31 protrudes (overhangs) in the +X direction from the semiconductor chip 22 in planar view so as not to cover the metal pads 22a. In this case, the possibility of cracking of the semiconductor chip 31 increases when the bonding wires W31 are bonded to the metal pads 31a. In the comparative example, the thickness of the semiconductor chip 31 is thicker than the thicknesses of the other semiconductor chips to prevent the semiconductor chip 31 from cracking.

In contrast, the metal pads P1-P4 in the present embodiment are arranged in line on a channel-by-channel basis in the +X and +Y directions from the semiconductor chips 11-42 respectively (FIG. 2). This allows the lengths of the bonding wires W11, W21, W31, and W41 to be shorter. The position of each metal pad P1 in the X direction is within the range between the long side in the +X direction and the long side in the −X direction of the semiconductor chips 11-12, and the position of each metal pad P2 in the Y direction is within the range between the long side in the +Y direction and the long side in the −Y direction of the semiconductor chips 21-22. Similarly, the position of each metal pad P3 in the X direction is within the range between the long side in the +X direction and the long side in the −X direction of the semiconductor chips 31-32, and the position of each metal pad P4 in the Y direction is in the range between the long side in the +Y direction and the long side in the −Y direction of the semiconductor chips 41-42. In this case, preferably, the position of each metal pad P1 in the X direction is as close as possible to the center line between the long side in the +X and −X directions of the semiconductor chips 11-12, and the same is true for the metal pads P2-P4.

The stairsteps of the semiconductor chips 11-42 in the present embodiment extend not only in the +X direction but also in the +Y direction (FIG. 2). This allows the angles of the bonding wires W11, W21, W31, and W41 with respect to the top surface of the substrate 1 to be smaller.

In the present embodiment, the semiconductor chip 22 is present in the −Z direction from the metal pads 31a (FIG. 1). This makes it possible to reduce the possibility of cracking of the semiconductor chip 31 when the bonding wires W31 are bonded to the metal pads 31a even when the semiconductor chips 31-42 are thin.

As described above, in the present embodiment, the semiconductor chips 11-42 are spirally stacked, and the metal pads P1-P4 are arranged in the +X and +Y directions from the semiconductor chips 11-42. In the present embodiment, the metal pads 21a-22a are located to overlap with the semiconductor chip 12, the metal pads 31a-32a are located to overlap with the semiconductor chip 22, and the metal pads 41a-42a are located to overlap with the semiconductor chip 32. In this way, the present embodiment makes it possible to stack the semiconductor chips 11-42 suitably for mitigating various problems in the comparative example.

Note that the metal pads 21a-22a may be arranged so that all of the metal pads 21a overlap with the semiconductor chip 12 and only some of the metal pads 22a overlap with the semiconductor chip 12. This is allowable because the possibility of cracking of the semiconductor chip 22 when the bonding wires W22 are bonded to the metal pads 22a is lower than the possibility of cracking of the semiconductor chip 21 when the bonding wires W21 are bonded to the metal pads 21a. Similarly, the metal pads 31a-32a may be arranged so that all of the metal pads 31a overlap with the semiconductor chip 22 and only some of the metal pads 32a overlap with the semiconductor chip 22. Likewise, the metal pads 41a-42a may be arranged so that all of the metal pads 41a overlap with the semiconductor chip 32 and only some of the metal pads 42a overlap with the semiconductor chip 32.

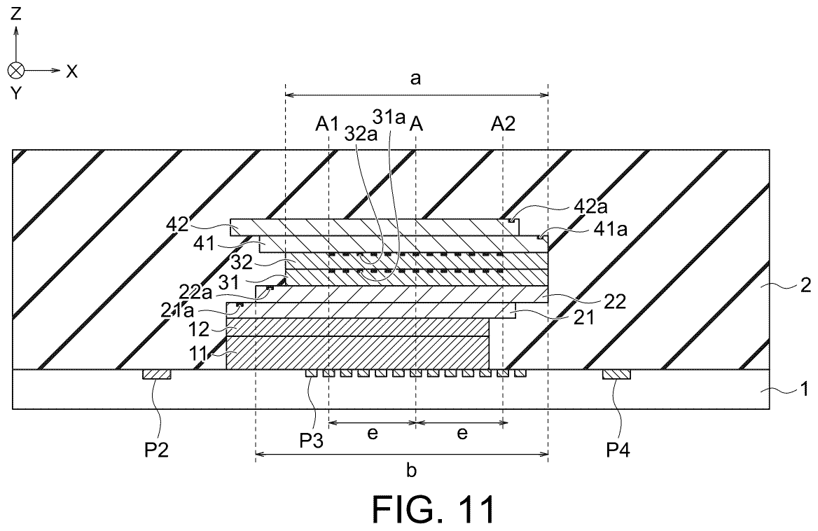

FIG. 11 is a cross-sectional view for describing the structure of the semiconductor device of the first embodiment.

FIG. 11 shows the semiconductor chips 11-42 arranged in a spiral extending in the Z direction, as in FIG. 1. However, in FIG. 11, the bonding wires W11-W42 are omitted to make various dashed lines and arrows easier to see.

FIG. 11 shows the length “a” [mm] of the short sides of the top surface of the semiconductor chips 11-42 and the length “b” [mm] of the long sides of the top surface of the semiconductor chips 11-42. FIG. 11 further shows the center line (center plane) A of the semiconductor chips 31-32 and lines (planes) A1 and A2 passing through the outermost metal pads 31a-32a of the metal pads 31a-32a of the semiconductor chips 31-32. The line A1 passes through the outermost parts of the outermost metal pads 31a-32a in the −X direction, and the line A2 passes through the outermost parts of the outermost metal pads 31a-32a in the +X direction. FIG. 11 further shows the distance “e” [mm] between the center line A and each of the lines A1 and A2.

Since the length “a” represents the length of the short sides and the length “b” represents the length of the long sides, the length “a” and the length “b” satisfy a<b. In the present embodiment, the shape of the top surfaces of the semiconductor chips 11-42 is, for example, a rectangle that is approximate to a square. In this case, the length “a” is close to the length “b”.

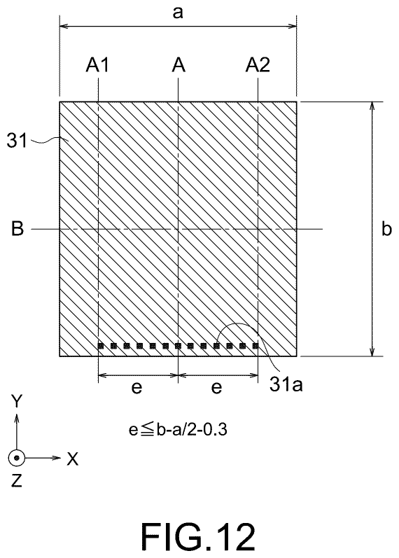

FIG. 12 is a plan view for describing the structure of the semiconductor device of the first embodiment.

In FIG. 12, the center line A described above extends parallel to the Y direction. The center line A shown in FIG. 12 extends parallel to each long side of the semiconductor chip 31 and passes through the center of each short side of the semiconductor chip 31. In FIG. 12, the lines A1 and A2 above also extend parallel to the Y direction. FIG. 12 further shows the length “a”, length “b”, and the distance “e” described above.

In the present embodiment, it is desirable that the metal pads 31a of the semiconductor chip 31 are arranged so as to satisfy the expression e≤b−a/2−0.3. This makes it possible to prevent the metal pads 31a from being located outside the top surface of the semiconductor chip 22 even if some error occurs in the position of the metal pads 31a or the like. The value 0.3 [mm] in the above expression corresponds to an offset.

In the present embodiment, it is desirable that the metal pads 11a-42a of the semiconductor chips 11-42 other than the semiconductor chip 31 are also arranged so as to satisfy the above expression. In this case, the distance “e” in each semiconductor chip is the distance between the center line A passing through the center of each short side of the semiconductor chip and each of the lines A1 and A2 passing through the outermost metal pads of the semiconductor chip. Note that the center lines A in the semiconductor chips 11, 12, 31, and 32 are straight lines parallel to the Y direction, and the center lines A in the semiconductor chips 21, 22, 41, and 42 are straight lines parallel to the X direction.

As described above, in the present embodiment, the metal pads 21a-22a are located at a position where they overlap with the semiconductor chip 12, the metal pads 31a-32a are located at a position where they overlap with the semiconductor chip 22, and the metal pads 41a-42a are located at a position where they overlap with the semiconductor chip 32. Consequently, the present embodiment makes it possible to reduce the possibility of cracking of the semiconductor chips 21-42 when the bonding wires W21-W42 are bonded to the metal pads 21a-42a, and therefore to stack the semiconductor chips 11-42 suitably.

### Second Embodiment

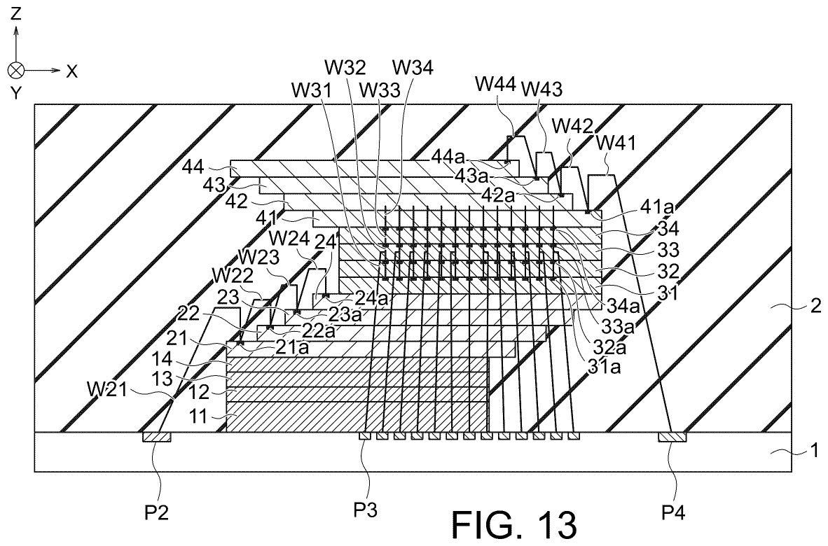

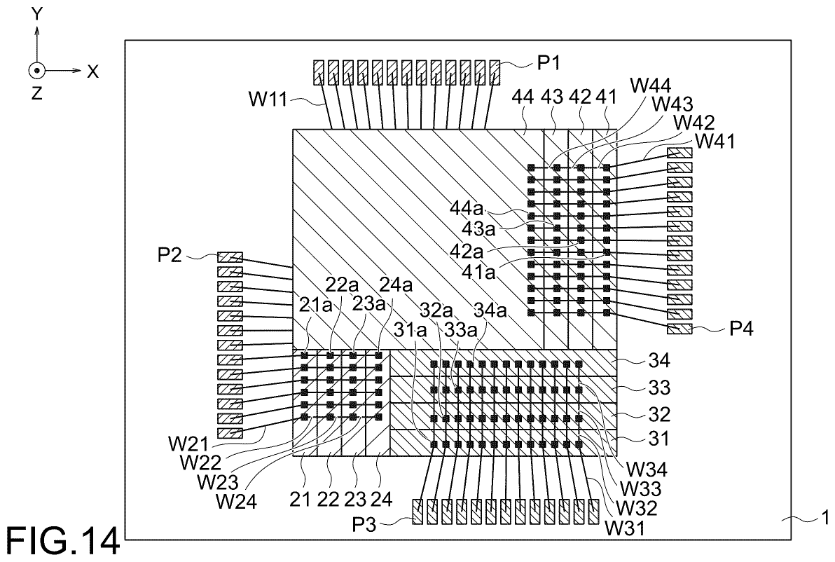

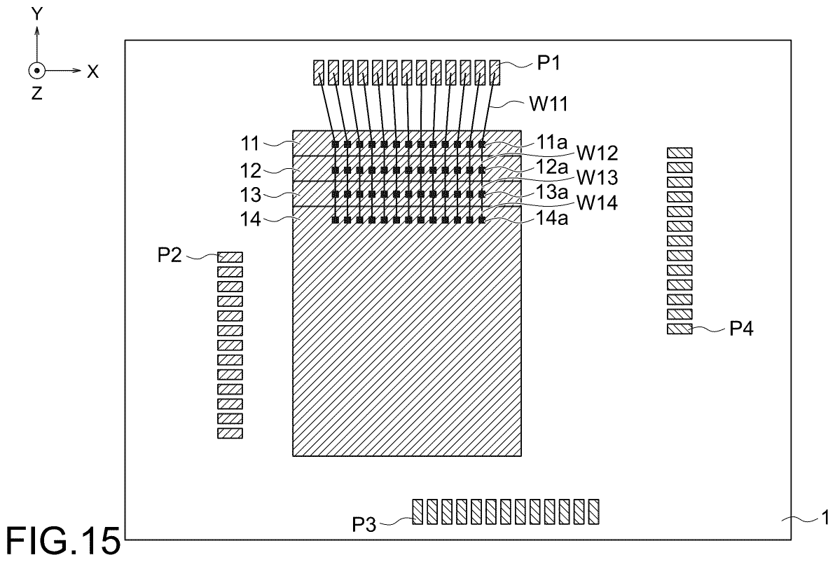

FIGS. 13 and 14 are a cross-sectional view and a plan view, respectively, illustrating the structure of a semiconductor device of the second embodiment. FIGS. 15 to 17 are plan views illustrating a method of manufacturing the semiconductor device of the second embodiment. FIGS. 13 to 17 correspond to FIGS. 1 to 5, respectively.

In addition to the components of the semiconductor device of the first embodiment, the semiconductor device of the present embodiment includes semiconductor chips 13-14 electrically connected to the metal pads P1, semiconductor chips 23-24 electrically connected to the metal pads P2, semiconductor chips 33-34 electrically connected to the metal pads P3, and semiconductor chips 43-44 electrically connected to the metal pads P4 (FIGS. 13 and 14). As with the semiconductor chips 11-12, the semiconductor chips 13-14 are an example of the one or more first chips. As with the semiconductor chips 21-22, the semiconductor chips 23-24 are an example of the one or more second chips. As with the semiconductor chips 31-32, the semiconductor chips 33-34 are an example of the one or more third chips. As with the semiconductor chips 41-42, the semiconductor chips 43-44 are an example of the one or more fourth chips. These 16 semiconductor chips 11-44 are, for example, semiconductor memory chips.

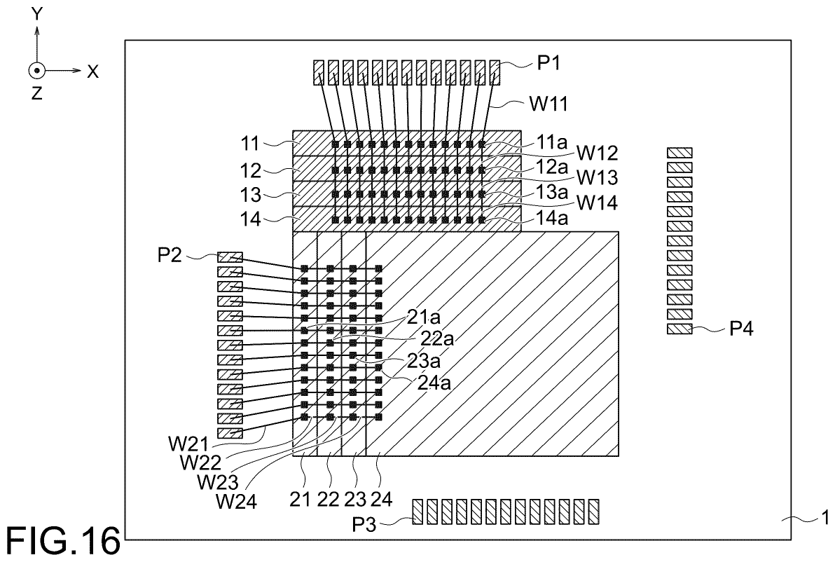

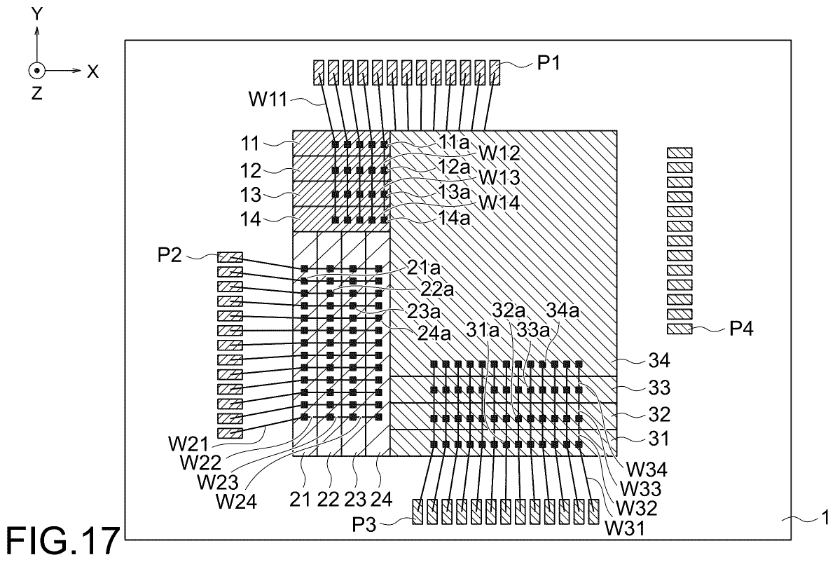

The semiconductor device of the present embodiment is manufactured by stacking the semiconductor chips 11-44 on the substrate 1 in sequence. First, the metal pads P1-P4 are formed on the top surface of the substrate 1, and the semiconductor chips 11-14 are stacked in sequence on the substrate 1 (FIG. 15). Next, the semiconductor chips 21-24 are stacked in sequence on the semiconductor chip 14 (FIG. 16). Then, the semiconductor chips 31-34 are stacked in sequence on the semiconductor chip 24 (FIG. 17). After that, the semiconductor chips 41-44 are stacked in sequence on the semiconductor chip 34, and the resin layer 2 is formed on the substrate 1 (FIGS. 13 and 14).

In the following, the structure of the semiconductor device of the present embodiment will be described with reference to FIGS. 13 to 17.

### [Metal Pads P1-P4]

The metal pads P1-P4 are arranged around the semiconductor chips 11-44 on the substrate 1, as shown in FIG. 14. The shapes and arrangements of the metal pads P1-P4 in the present embodiment are the same as those of the metal pads P1-P4 in the first embodiment. The semiconductor chips 11-44 in the present embodiment have the same shapes and thicknesses as those of the semiconductor chips 11-42 in the first embodiment.

### [Semiconductor Chips 11-14]

The semiconductor chips 11-14 are located in the −Y direction from the metal pads P1 and are electrically connected to the metal pads P1 (FIG. 15). The (rectangular) top surfaces of the semiconductor chips 11-14 have short sides parallel to the X direction and long sides parallel to the Y direction. The semiconductor chips 11-14 in the present embodiment are stacked on the substrate 1 to form stairsteps in the −Y direction, similar to the semiconductor chips 11-12 in the first embodiment.

The details of the semiconductor chips 13-14 in the present embodiment are the same as those of the semiconductor chips 11-12 in the first embodiment. The semiconductor chip 13 has a plurality of metal pads 13a provided on the top surface of the semiconductor chip 13 (FIG. 15). These metal pads 13a are electrically connected to the metal pads 12a by a plurality of bonding wires W13 so that the metal pads 13a are electrically connected to the metal pads P1. The semiconductor chip 14 has a plurality of metal pads 14a provided on the top surface of the semiconductor chip 14 (FIG. 15). These metal pads 14a are electrically connected to the metal pads 13a by a plurality of bonding wires W14 so that the metal pads 14a are electrically connected to the metal pads P1. As with the metal pads 11a-12a, the metal pads 13a-14a are an example of the one or more first chip pads.

### [Semiconductor Chips 21-24]

The semiconductor chips 21-24 are located in the +X direction from the metal pads P2 and are electrically connected to the metal pads P2 (FIG. 16). The (rectangular) top surfaces of the semiconductor chips 21-24 have short sides parallel to the Y direction and long sides parallel to the X direction. The semiconductor chips 21-24 in the present embodiment are stacked on the semiconductor chip 14 to form stairsteps in the +X direction, similar to the semiconductor chips 21-22 in the first embodiment.

The details of the semiconductor chips 23-24 in the present embodiment are the same as those of the semiconductor chips 21-22 in the first embodiment. The semiconductor chip 23 has a plurality of metal pads 23a provided on the top surface of the semiconductor chip 23 (FIG. 16). These metal pads 23a are electrically connected to the metal pads 22a by a plurality of bonding wires W23 so that the metal pads 23a are electrically connected to the metal pads P2. The semiconductor chip 24 has a plurality of metal pads 24a provided on the top surface of the semiconductor chip 24 (FIG. 16). These metal pads 24a are electrically connected to the metal pads 23a by a plurality of bonding wires W24 so that the metal pads 24a are electrically connected to the metal pads P2. As with the metal pads 21a-22a, the metal pads 23a-24a are an example of the one or more second chip pads.

In the present embodiment, the semiconductor chips 11-14 are arranged so that their short sides are parallel to the X direction and their long sides are parallel to the Y direction, forming stairsteps extending in the −Y direction. In contrast, the semiconductor chips 21-24 are arranged so that their short sides are parallel to the Y direction and their long sides are parallel to the X direction, forming stairsteps extending in the +X direction that intersects the −Y direction. As a result, these eight semiconductor chips 11-24 as a whole form an L-shape in planar view.

Each of the metal pads 21a-24a in the present embodiment is located at a position where it overlaps with the highest semiconductor chip 14 of the semiconductor chips 11-14 in planar view. The present embodiment makes it possible to reduce the possibility of cracking of the semiconductor chips 21-24 even when the semiconductor chips 21-24 are thin by virtue of the presence of the semiconductor chip 14 in the −Z direction from the metal pads 21a-24a. FIG. 13 shows the metal pads 21a-24a located at a position where they overlap with the semiconductor chip 14 in planar view.

### [Semiconductor Chips 31-34]

The semiconductor chips 31-34 are located in the +Y direction from the metal pads P3 and are electrically connected to the metal pads P3 (FIG. 17). The (rectangular) top surfaces of the semiconductor chips 31-34 have short sides parallel to the X direction and long sides parallel to the Y direction. The semiconductor chips 31-34 in the present embodiment are stacked on the semiconductor chip 24 to form stairsteps in the +Y direction, similar to the semiconductor chips 31-32 in the first embodiment.

The details of the semiconductor chips 33-34 in the present embodiment are the same as those of the semiconductor chips 31-32 in the first embodiment. The semiconductor chip 33 has a plurality of metal pads 33a provided on the top surface of the semiconductor chip 33 (FIG. 17). These metal pads 33a are electrically connected to the metal pads 32a by a plurality of bonding wires W33 so that the metal pads 33a are electrically connected to the metal pads P3. The semiconductor chip 34 has a plurality of metal pads 34a provided on the top surface of the semiconductor chip 34 (FIG. 17). These metal pads 34a are electrically connected to the metal pads 33a by a plurality of bonding wires W34 so that the metal pads 34a are electrically connected to the metal pads P3. As with the metal pads 31a-32a, the metal pads 33a-34a are an example of the one or more third chip pads.

In the present embodiment, the semiconductor chips 21-24 are arranged so that their short sides are parallel to the Y direction and their long sides are parallel to the X direction, forming stairsteps extending in the +X direction. In contrast, the semiconductor chips 31-34 are arranged so that their short sides are parallel to the X direction and their long sides are parallel to the Y direction, forming stairsteps extending in the +Y direction that intersects the +X direction. As a result, these eight semiconductor chips 21-34 as a whole form an L-shape in planar view.

Each of the metal pads 31a-34a in the present embodiment is located at a position where it overlaps with the highest semiconductor chip 24 of the semiconductor chips 21-24 in planar view. The present embodiment makes it possible to reduce the possibility of cracking of the semiconductor chips 31-34 even when the semiconductor chips 31-34 are thin by virtue of the presence of the semiconductor chip 24 in the −Z direction from the metal pads 31a-34a. FIG. 13 shows the metal pads 31a-34a located at a position where they overlap with the semiconductor chip 24 in planar view.

### [Semiconductor Chips 41-44]

The semiconductor chips 41-44 are located in the −X direction from the metal pads P4 and are electrically connected to the metal pads P4 (FIG. 14). The (rectangular) top surfaces of the semiconductor chips 41-44 have short sides parallel to the Y direction and long sides parallel to the X direction. The semiconductor chips 41-44 in the present embodiment are stacked on the semiconductor chip 32 to form stairsteps in the −X direction, similar to the semiconductor chips 41-42 in the first embodiment.

The details of the semiconductor chips 43-44 in the present embodiment are the same as those of the semiconductor chips 41-42 in the first embodiment. The semiconductor chip 43 has a plurality of metal pads 43a provided on the top surface of the semiconductor chip 43 (FIG. 14). These metal pads 43a are electrically connected to the metal pads 42a by a plurality of bonding wires W43 so that the metal pads 43a are electrically connected to the metal pads P4. The semiconductor chip 44 has a plurality of metal pads 44a provided on the top surface of the semiconductor chip 44 (FIG. 14). These metal pads 44a are electrically connected to the metal pads 43a by a plurality of bonding wires W44 so that the metal pads 44a are electrically connected to the metal pads P4. As with the metal pads 41a-42a, the metal pads 43a-44a are an example of the one or more fourth chip pads.

In the present embodiment, the semiconductor chips 31-34 are arranged so that their short sides are parallel to the X direction and their long sides are parallel to the Y direction, forming stairsteps extending in the +Y direction. In contrast, the semiconductor chips 41-44 are arranged so that their short sides are parallel to the Y direction and their long sides are parallel to the X direction, forming stairsteps extending in the −X direction that intersects the +Y direction. As a result, these eight semiconductor chips 31-44 as a whole form an L-shape in planar view.

Each of the metal pads 41a-44a in the present embodiment is located at a position where it overlaps with the highest semiconductor chip 34 of the semiconductor chips 31-34 in planar view. The present embodiment makes it possible to reduce the possibility of cracking of the semiconductor chips 41-44 even when the semiconductor chips 41-44 are thin by virtue of the presence of the semiconductor chip 34 in the −Z direction from the metal pads 41a-44a. FIG. 13 shows the metal pads 41a-44a located at a position where they overlap with the semiconductor chip 34 in planar view.

In the present embodiment, the semiconductor chips 11-14 form stairsteps extending in the −Y direction, and the semiconductor chips 21-24 form stairsteps extending in the +X direction. As a result, the direction in which the stairsteps of the semiconductor chips 21-24 extend (+X direction) is rotated 90 degrees counterclockwise with respect to the direction in which the stairsteps of the semiconductor chips 11-14 extend (−Y direction) in planar view. Similarly, the direction in which the stairsteps of the semiconductor chips 31-34 extend (+Y direction) is rotated 90 degrees counterclockwise with respect to the direction in which the stairsteps of the semiconductor chips 21-24 extend (+X direction) in planar view. Likewise, the direction in which the stairsteps of the semiconductor chips 41-44 extend (−X direction) is rotated 90 degrees counterclockwise with respect to the direction in which the stairsteps of the semiconductor chips 31-34 extend (+Y direction) in planar view. In this way, these semiconductor chips 11-44 are arranged in a spiral extending in the Z direction.

As described above, in the present embodiment, the metal pads 21a-24a are located at a position where they overlap with the semiconductor chip 14, the metal pads 31a-34a are located at a position where they overlap with the semiconductor chip 24, and the metal pads 41a-44a are located at a position where they overlap with the semiconductor chip 34. Consequently, the present embodiment makes it possible to reduce the possibility of cracking of the semiconductor chips 21-44 when the bonding wires W21-W44 are bonded to the metal pads 21a-44a, and therefore to stack the semiconductor chips 11-44 suitably.

Note that the metal pads 21a-24a may be arranged so that all of the metal pads 21a overlap with the semiconductor chip 14 and only some of the metal pads 22a-24a overlap with the semiconductor chip 14. This is allowable because the possibility of cracking of the semiconductor chips 22-24 when the bonding wires W22-W24 are bonded to the metal pads 22a-24a is lower than the possibility of cracking of the semiconductor chip 21 when the bonding wires W21 are bonded to the metal pads 21a. Similarly, the metal pads 31a-34a may be arranged so that all of the metal pads 31a overlap with the semiconductor chip 24 and only some of the metal pads 32a-34a overlap with the semiconductor chip 24. Likewise, the metal pads 41a-44a may be arranged so that all of the metal pads 41a overlap with the semiconductor chip 34 and only some of the metal pads 42a-44a overlap with the semiconductor chip 34.

### Third Embodiment

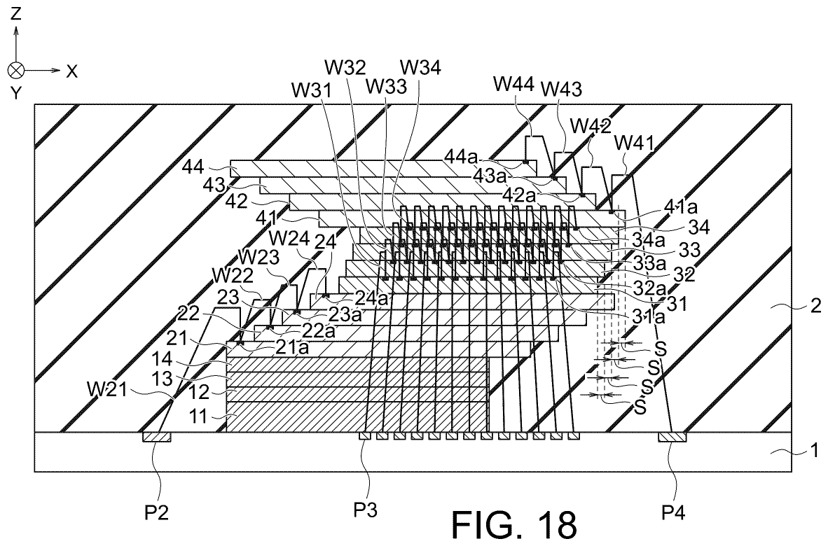

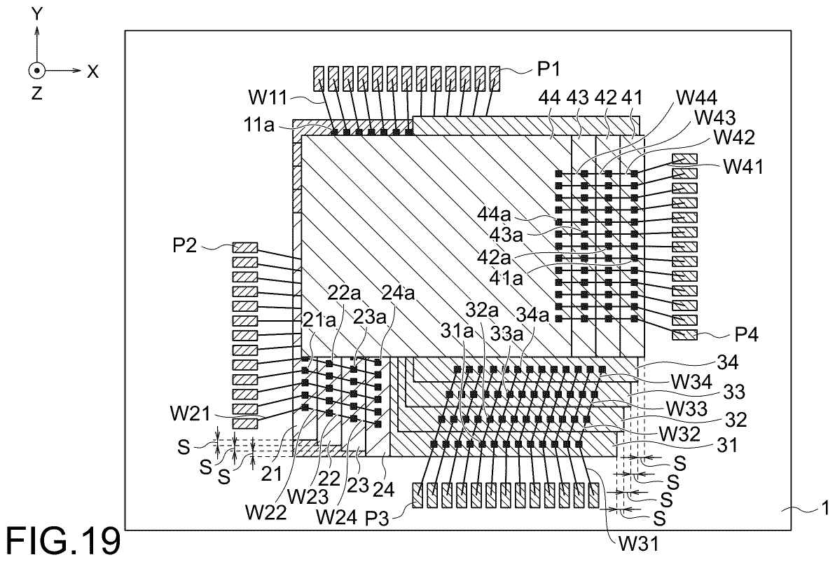

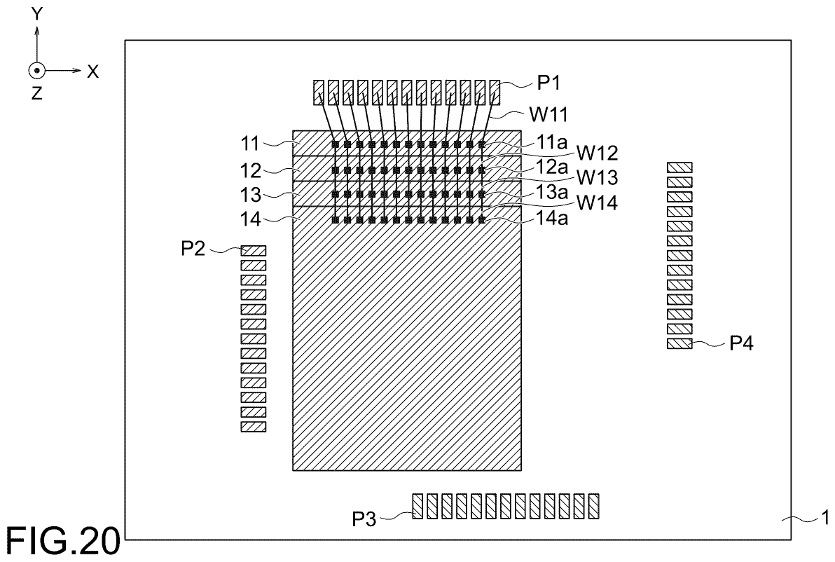

FIGS. 18 and 19 are a cross-sectional view and a plan view, respectively, illustrating the structure of a semiconductor device of the third embodiment. FIGS. 20 to 22 are plan views illustrating a method of manufacturing the semiconductor device of the third embodiment. FIGS. 18 to 22 correspond to FIGS. 1 to 5, respectively.

The semiconductor device of the present embodiment includes the same components as those of the semiconductor device of the second embodiment, as shown in FIGS. 18 and 19.

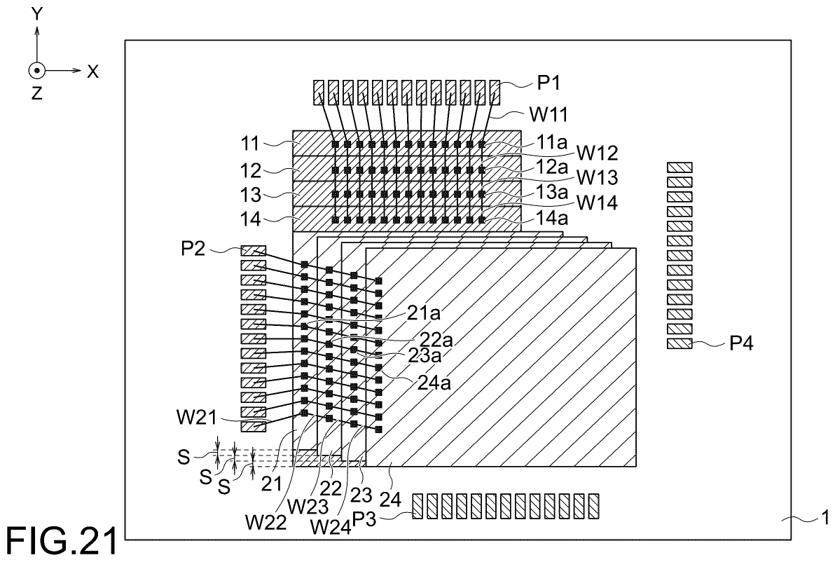

The semiconductor chips 21-24 in the present embodiment, however, are stacked on the semiconductor chip 14 with an offset “S” with respect to each other in the −Y direction (FIG. 21). In consequence, the semiconductor chips 21-24 in the present embodiment form gentle stairsteps in the +X direction and form steep stairsteps in the −Y direction. The offset “S” of the semiconductor chips 21-24 is also shown in FIG. 19. The semiconductor chips 21-24 in the present embodiment are arranged on the semiconductor chip 14 so that the long side in the −Y direction of the semiconductor chip 24 overlaps with the short side in the −Y direction of the semiconductor chip 14 in planar view.

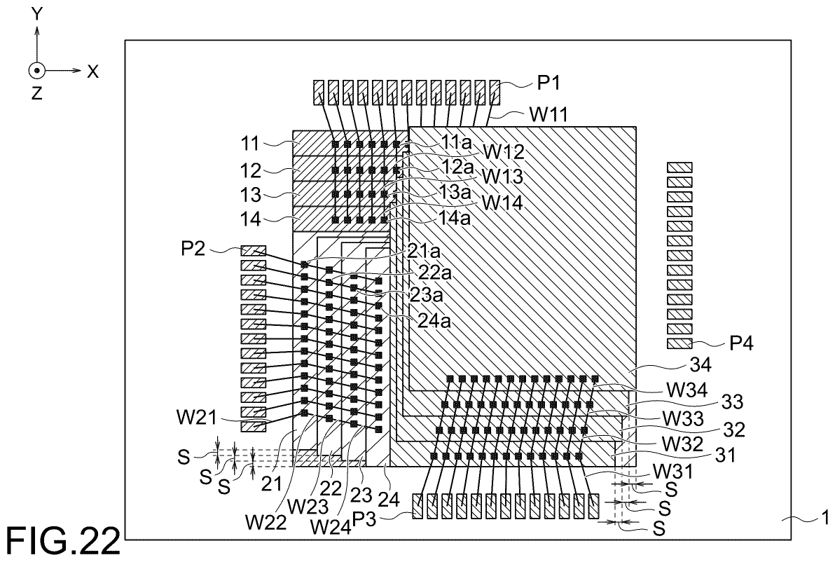

Similarly, the semiconductor chips 31-34 in the present embodiment are stacked on the semiconductor chip 24 with an offset “S” with respect to each other in the +X direction (FIG. 22). In consequence, the semiconductor chips 31-34 in the present embodiment form gentle stairsteps in the +Y direction and form steep stairsteps in the +X direction. The offset “S” of the semiconductor chips 31-34 is also shown in FIGS. 18 and 19. The semiconductor chips 31-34 in the present embodiment are arranged on the semiconductor chip 24 so that the long side in the +X direction of the semiconductor chip 34 overlaps with the short side in the +X direction of the semiconductor chip 24 in planar view.

In contrast, the semiconductor chips 11-14 in the present embodiment are stacked on the substrate 1 without the offset “S” with respect to each other in the +X direction (FIG. 20). Similarly, the semiconductor chips 41-44 in the present embodiment are stacked on the semiconductor chip 34 without the offset “S” with respect to each other in the +Y direction (FIG. 19). The offset “S” in the present embodiment is not provided for either the semiconductor chips 11-14 in the lowest semiconductor chip group or the semiconductor chips 41-44 in the highest semiconductor chip group, but for the semiconductor chips 21-34 in the other semiconductor chip groups. Here, the semiconductor chip group including the semiconductor chips 11-14 means a group consisting of semiconductor chips electrically connected to the metal pads P1, and the semiconductor chip group including the semiconductor chips 21-24 means a group consisting of semiconductor chips electrically connected to the metal pads P2. Similarly, the semiconductor chip group including the semiconductor chips 31-34 means a group consisting of semiconductor chips electrically connected to the metal pads P3, and the semiconductor chip group including the semiconductor chips 41-44 means a group consisting of semiconductor chips electrically connected to the metal pad P4.

The present embodiment makes it possible to make, for example, the positional relationship between the metal pads 31a-34a and the metal pads P3 more suitable by providing the offset “S” in the semiconductor chips 21-24. Similarly, the present embodiment makes it possible to make, for example, the positional relationship between the metal pads 41a-44a and the metal pad P4 more suitable by providing the offset “S” in the semiconductor chips 31-34. This is because the bonding wires for the lowest and highest semiconductor chip groups can be shorter without the offset “S”, but the bonding wires for the other semiconductor chip groups can be shorter with the offset “S”. This is used, for example, when the size of a semiconductor package has to be kept constant and it is therefore difficult to freely change the positions of the metal pads P1-P4.

### Fourth Embodiment

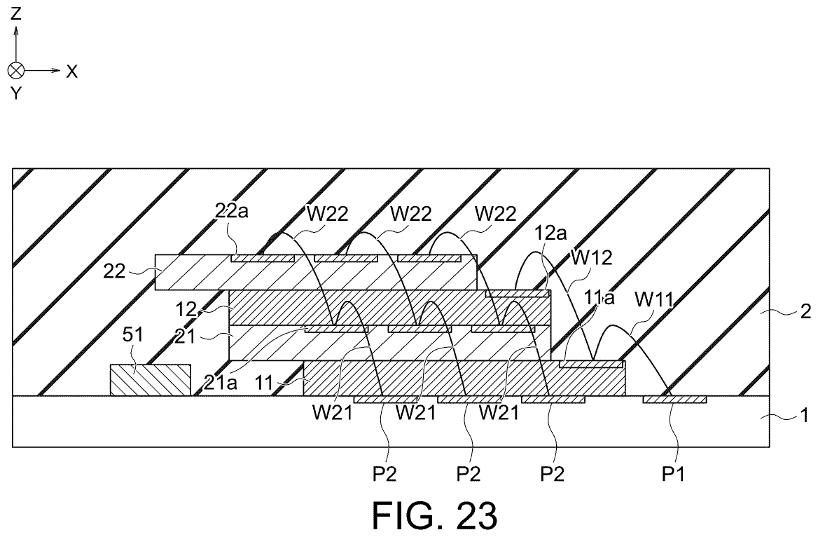

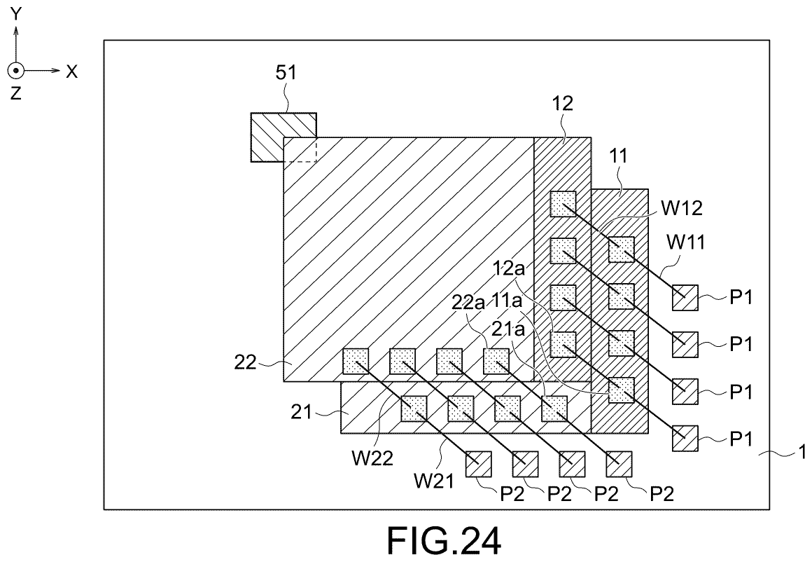

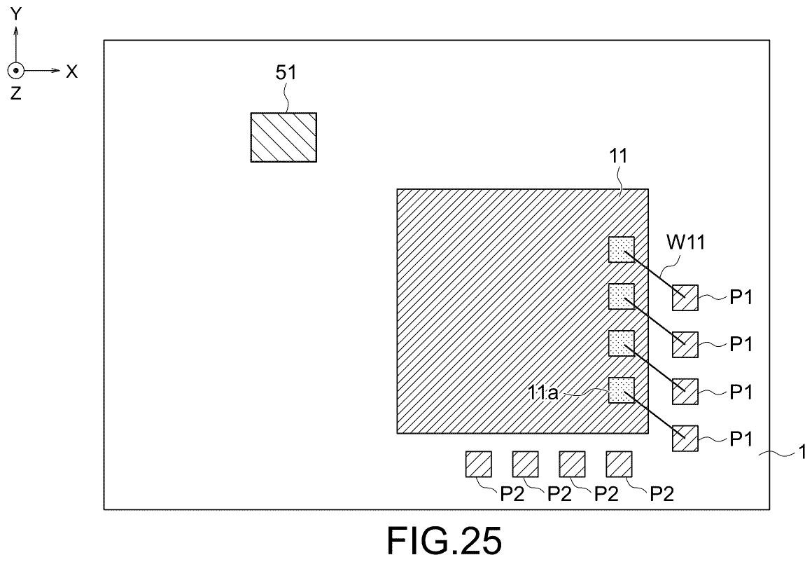

FIGS. 23 and 24 are a cross-sectional view and a plan view, respectively, illustrating the structure of a semiconductor device of the fourth embodiment. FIGS. 25 to 27 are plan views illustrating a method of manufacturing the semiconductor device of the fourth embodiment. FIGS. 23 to 27 correspond to FIGS. 1 to 5, respectively.

Similar to the semiconductor device of the first embodiment, the semiconductor device of the present embodiment includes a substrate 1, a resin layer 2, a plurality of metal pads P1, a plurality of metal pads P2, a plurality of semiconductor chips 11-12 electrically connected to the metal pads P1, and a plurality of semiconductor chips 21-22 electrically connected to the metal pads P2 (FIGS. 23 and 24).

These four semiconductor chips 11-22, however, are stacked on the substrate 1 in the following order: the semiconductor chip 11, the semiconductor chip 21, the semiconductor chip 12, and the semiconductor chip 22. The semiconductor chip 11 in the present embodiment is an example of the one or more first chips. The semiconductor chip 21 in the present embodiment is an example of the one or more second chips. The semiconductor chip 12 in the present embodiment is an example of one or more third chips. The semiconductor chip 22 in the present embodiment is an example of one or more fourth chips.

Furthermore, the semiconductor chips 11-22 in the present embodiment are located in the −X direction from the metal pads P1 and in the +Y direction from the metal pads P2. The −X direction in the present embodiment is an example of a first direction and the +Y direction in the present embodiment is an example of a second direction. As with the metal pads P1 in the first embodiment, the metal pads P1 in the present embodiment is an example of the one or more first substrate pads, and as with the metal pads P2 in the first embodiment, the metal pads P2 in the present embodiment is an example of the one or more second substrate pads.

The semiconductor device of the present embodiment further includes a control chip 51 that is located on the substrate 1 and controls the operation of the semiconductor chips 11-22. The control chip 51 in the present embodiment is located at a position where it partially overlaps with the semiconductor chip 22 in planar view (FIGS. 23 and 24).

In addition, the semiconductor device of the present embodiment does not include any of metal pads P3, metal pads P4, a plurality of semiconductor chips 31-32 electrically connected to the metal pads P3, and a plurality of semiconductor chips 41-42 electrically connected to the metal pads P4.

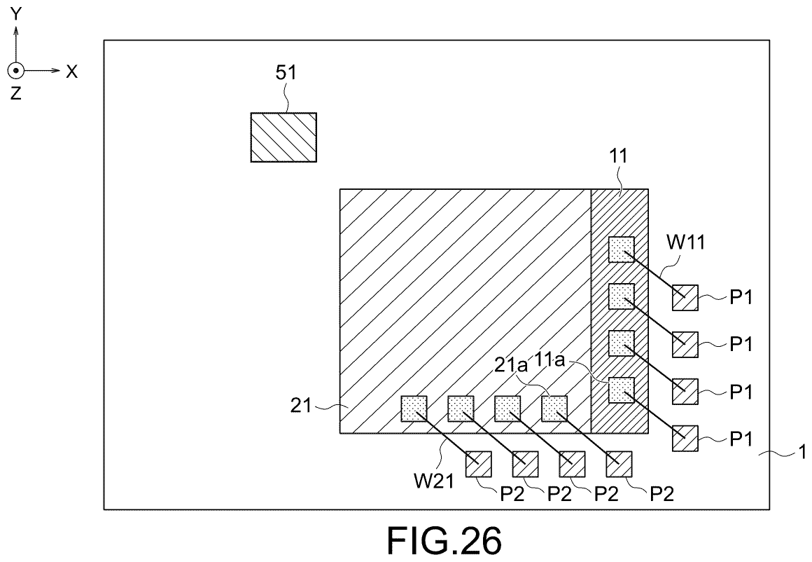

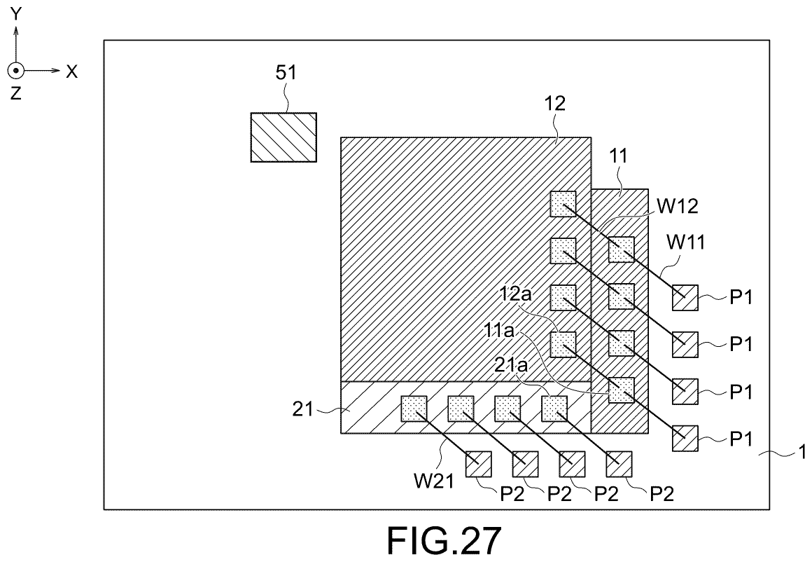

The semiconductor device of the present embodiment is manufactured by arranging the semiconductor chips 11-22 and the control chip 51 on the substrate 1. First, the metal pads P1-P2 are formed on the top surface of the substrate 1, and the semiconductor chip 11 and the control chip 51 are arranged on the substrate 1 (FIG. 25). Next, the semiconductor chip 21 is located on the semiconductor chip 11 (FIG. 26). Then, the semiconductor chip 12 is located on the semiconductor chip 21 (FIG. 27). After that, the semiconductor chip 22 is located on the semiconductor chip 12, and the resin layer 2 is formed on the substrate 1 (FIGS. 23 and 24). In FIGS. 23 and 24, the control chip 51 has a portion provided under the semiconductor chip 22 in planar view.

In the following, the structure of the semiconductor device of the present embodiment will be described with reference to FIGS. 23 to 27.

### [Metal Pads P1-P2]

The metal pads P1-P2 are located in the +X and −Y directions from the semiconductor chip 11-22 on the substrate 1, respectively, as shown in FIG. 24. Specifically, the metal pads P1 are located in the +X direction from the semiconductor chips 11-22 and are arranged in line along the Y direction. The metal pads P2 are located in the −Y direction from the semiconductor chips 11-22 and are arranged in line along the X direction.

In the present embodiment, the semiconductor chips 11-22 have congruent shapes in planar view. Specifically, the shapes of the semiconductor chips 11-22 are congruent squares in planar view. The semiconductor chips 11-22 in the present embodiment have the same thickness (FIG. 23). In the present embodiment, the thicknesses of the semiconductor chips 11-22 are set to 50 μm or less (e.g., 20-50 μm). Note that the shapes and thicknesses of the semiconductor chips 11-22 may be different from those in the present embodiment.

### [Semiconductor Chip 11]

The semiconductor chip 11 is located in the −X direction from the metal pads P1 and is electrically connected to the metal pads P1 (FIG. 25). The (square) top surface of the semiconductor chip 11 has two sides parallel to the X direction and two sides parallel to the Y direction.

The semiconductor chip 11 has a plurality of metal pads 11a provided on the top surface of the semiconductor chip 11 (FIG. 25). These metal pads 11a are electrically connected to the metal pads P1 by a plurality of bonding wires W11. The metal pads 11a in the present embodiment are an example of one or more first chip pads.

### [Semiconductor Chip 21]

The semiconductor chip 21 is located in the +Y direction from the metal pads P2 and is electrically connected to the metal pads P2 (FIG. 26). The (square) top surface of the semiconductor chip 21 has two sides parallel to the X direction and two sides parallel to the Y direction. The semiconductor chip 21 is located on the semiconductor chip 11, not at a position where it completely overlaps with the semiconductor chip 11, but at a position where it partially overlaps with the semiconductor chip 11 in planar view. Specifically, the center of gravity of the top surface of the semiconductor chip 21 is located in the −X direction from the center of gravity of the top surface of the semiconductor chip 11. Thus, the semiconductor chips 11 and 21 are stacked on the substrate 1 to form stairsteps in the −X direction.

The semiconductor chip 21 has a plurality of metal pads 21a provided on the top surface of the semiconductor chip 21 (FIG. 26). These metal pads 21a are electrically connected to the metal pads P2 by a plurality of bonding wires W21. The metal pads 21a in the present embodiment are an example of one or more second chip pads.

Each of the metal pads 21a in the present embodiment is located at a position where it overlaps with the semiconductor chip 11 in planar view. The present embodiment makes it possible to reduce the possibility of cracking of the semiconductor chip 21 even when the semiconductor chip 21 is thin by virtue of the presence of the semiconductor chip 11 in the −Z direction from the metal pads 21a. FIG. 23 shows the metal pads 21a located at a position where they overlap with the semiconductor chip 11 in planar view.

### [Semiconductor Chip 12]

The semiconductor chip 12 is located in the −X direction from the metal pads P1 and is electrically connected to the metal pads P1 (FIG. 27). The (square) top surface of the semiconductor chip 12 has two sides parallel to the X direction and two sides parallel to the Y direction. The semiconductor chip 12 is located on the semiconductor chip 21, not at a position where it completely overlaps with the semiconductor chip 21, but at a position where it partially overlaps with the semiconductor chip 21 in planar view. Specifically, the center of gravity of the top surface of the semiconductor chip 12 is located in the +Y direction from the center of gravity of the top surface of the semiconductor chip 21. Thus, the semiconductor chips 21 and 12 are stacked on the semiconductor chip 11 to form stairsteps in the +Y direction.

The semiconductor chip 12 has a plurality of metal pads 12a provided on the top surface of the semiconductor chip 12 (FIG. 27). These metal pads 12a are electrically connected to the metal pads 11a by a plurality of bonding wires W12 so that the metal pads 12a are electrically connected to the metal pads P1. The metal pads 12a in the present embodiment are an example of one or more third chip pads.

Each of the metal pads 12a in the present embodiment is located at a position where it overlaps with the semiconductor chip 21 in planar view. The present embodiment makes it possible to reduce the possibility of cracking of the semiconductor chip 12 even when the semiconductor chip 12 is thin by virtue of the presence of the semiconductor chip 21 in the −Z direction from the metal pads 12a. FIG. 23 shows the metal pads 12a located at a position where they overlap with the semiconductor chip 21 in planar view.

### [Semiconductor Chip 22]

The semiconductor chip 22 is located in the +Y direction from the metal pads P2 and is electrically connected to the metal pads P2 (FIG. 24). The (square) top surface of the semiconductor chip 22 has two sides parallel to the X direction and two sides parallel to the Y direction. The semiconductor chip 22 is located on the semiconductor chip 12, not at a position where it completely overlaps with the semiconductor chip 12, but at a position where it partially overlaps with the semiconductor chip 12 in planar view. Specifically, the center of gravity of the top surface of the semiconductor chip 22 is located in the −X direction from the center of gravity of the top surface of the semiconductor chip 12. Thus, the semiconductor chips 12 and 22 are stacked on the semiconductor chip 21 to form stairsteps in the −X direction.

The semiconductor chip 22 has a plurality of metal pads 22a provided on the top surface of the semiconductor chip 22 (FIG. 24). These metal pads 22a are electrically connected to the metal pads 21a by a plurality of bonding wires W22 so that the metal pads 22a are electrically connected to the metal pads P2. The metal pads 22a in the present embodiment are an example of one or more fourth chip pads.

Each of the metal pads 22a in the present embodiment is located at a position where it overlaps with the semiconductor chip 12 in planar view. The present embodiment makes it possible to reduce the possibility of cracking of the semiconductor chip 22 even when the semiconductor chip 22 is thin by virtue of the presence of the semiconductor chip 12 in the −Z direction from the metal pads 22a. FIG. 23 shows the metal pads 22a located at a position where they overlap with the semiconductor chip 12 in planar view.

In the present embodiment, the semiconductor chips 11 and 21 form stairsteps extending in the −X direction, and the semiconductor chips 21 and 12 form stairsteps extending in the +Y direction. As a result, the direction in which the stairsteps of the semiconductor chips 21 and 12 extend (+Y direction) is rotated 90 degrees clockwise with respect to the direction in which the stairsteps of the semiconductor chips 11 and 21 extend (−X direction) in planar view. In contrast, the direction in which the stairsteps of the semiconductor chips 12 and 22 extend (−X direction) is rotated 90 degrees counterclockwise with respect to the direction in which the stairsteps of the semiconductor chips 21 and 12 extend (+Y direction) in planar view. Thus, these semiconductor chips 11-22 form stairsteps extending in the upper left direction in planar view. (The term “upper left” here means upper left on the page. The same applies hereinafter.)

In consequence, the semiconductor device in the present embodiment has a space under the semiconductor chip 22 where the control chip 51 can be located. Specifically, such a space is created under the upper left corner of the semiconductor chip 22 in planar view. Thus, the control chip 51 in the present embodiment is located at a position where it partially overlaps with the semiconductor chip 22 in planar view. This makes it possible to secure a space to place the control chip 51 even if the top surface area of the substrate 1 is small.

As described above, in the present embodiment, the metal pads 21a are located at a position where they overlap with the semiconductor chip 11, the metal pads 12a are located at a position where they overlap with the semiconductor chip 21, and the metal pads 22a are located at a position where they overlap with the semiconductor chip 12. Consequently, the present embodiment makes it possible to reduce the possibility of cracking of the semiconductor chips 21, 12, and 22 when the bonding wires W21, W12, and W22 are bonded to the metal pads 21a, 12a, and 22a, and therefore to stack the semiconductor chips 11-22 suitably.

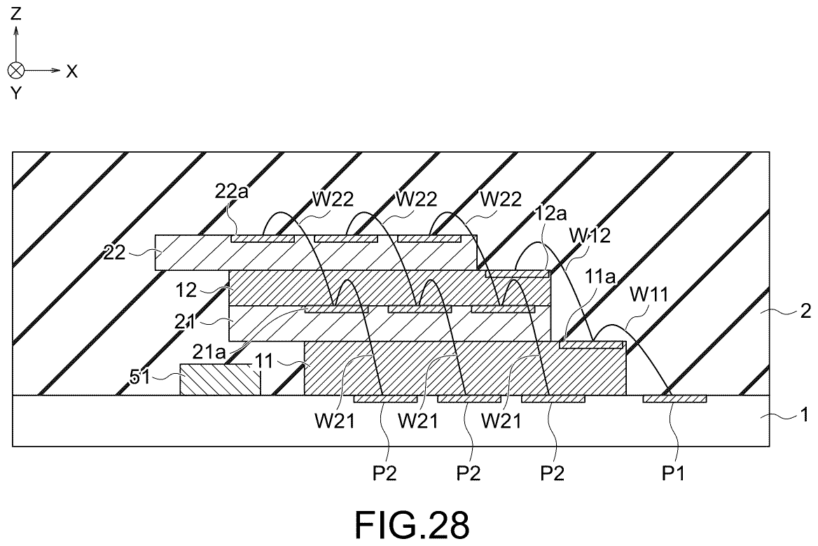

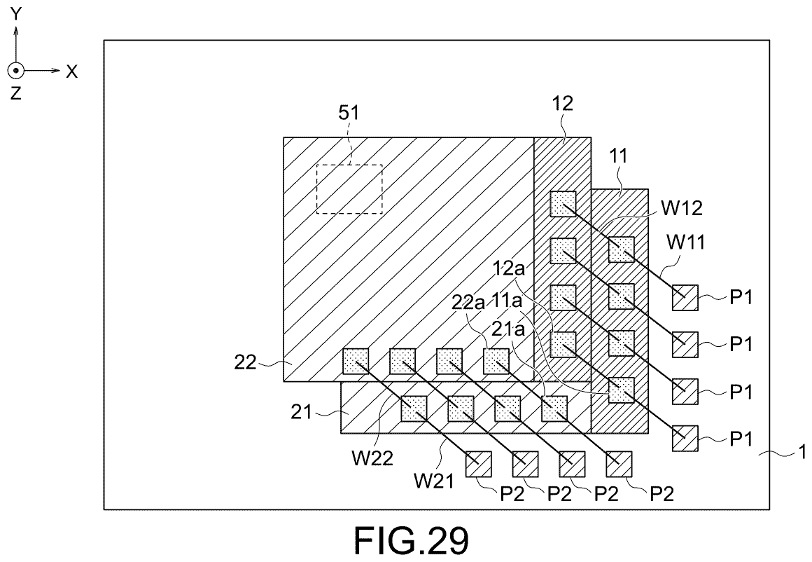

FIGS. 28 and 29 are a cross-sectional view and a plan view, respectively, illustrating the structure of a semiconductor device of the first variant example of the fourth embodiment.

The semiconductor device of this variant example includes the same components as those of the semiconductor device of the present embodiment, as shown in FIGS. 28 and 29. The thickness of the semiconductor chip 11 in this variant example is thicker than the thicknesses of the semiconductor chips 21, 12, and 22. As such, the control chip 51 in this variant example is located at a position where it completely overlaps with the semiconductor chip 22 in planar view (FIG. 29), and the whole of the control chip 51 is located in the −Z direction from the semiconductor chip 22. Furthermore, the control chip 51 in this variant example is located at a position where it partially overlaps with the semiconductor chips 21 and 12 in planar view (FIG. 28), and has a portion located in the −Z direction from the semiconductor chips 21 and 12 and a portion not located in the −Z direction from the semiconductor chips 21 and 12. This makes it possible to secure a space to place the control chip 51 even if the top surface area of the substrate 1 is smaller.

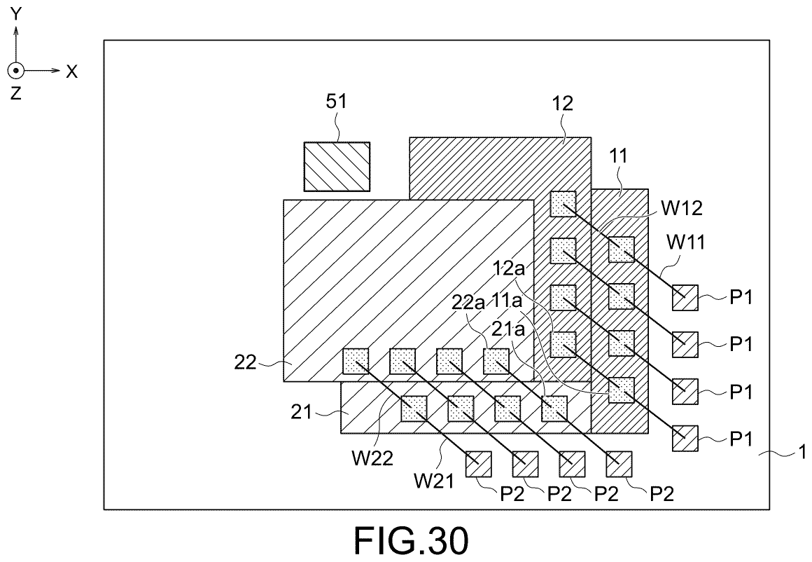

FIG. 30 is a plan view illustrating the structure of a semiconductor device of the second variant example of the fourth embodiment.

The semiconductor device of this variant example includes the same components as those of the semiconductor device of the present embodiment, as shown in FIG. 30. The shapes of the semiconductor chips 11-22 in this variant example, however, are congruent rectangles in planar view. As such, the, the control chip 51 in this variant example is located at a position where it does not overlap with the semiconductor chip 22 in planar view. Nevertheless, this variant example makes it possible to secure a space to place the control chip 51 near the upper left corner of the semiconductor chip 22 thanks to the rectangular shapes of the semiconductor chips 11-22.

### Variant Example of First Embodiment

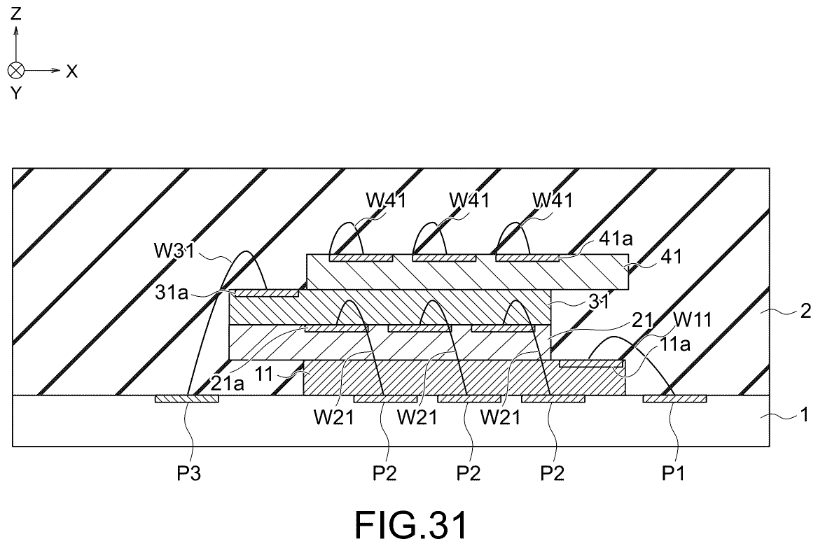

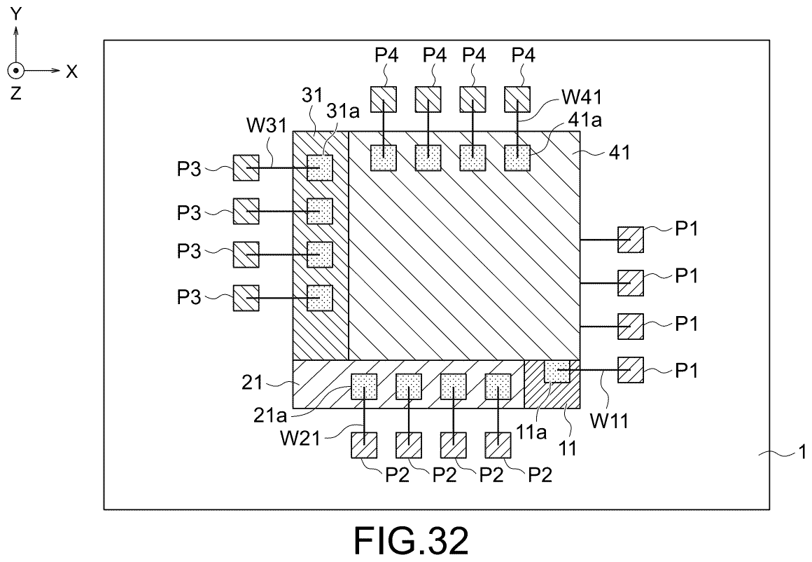

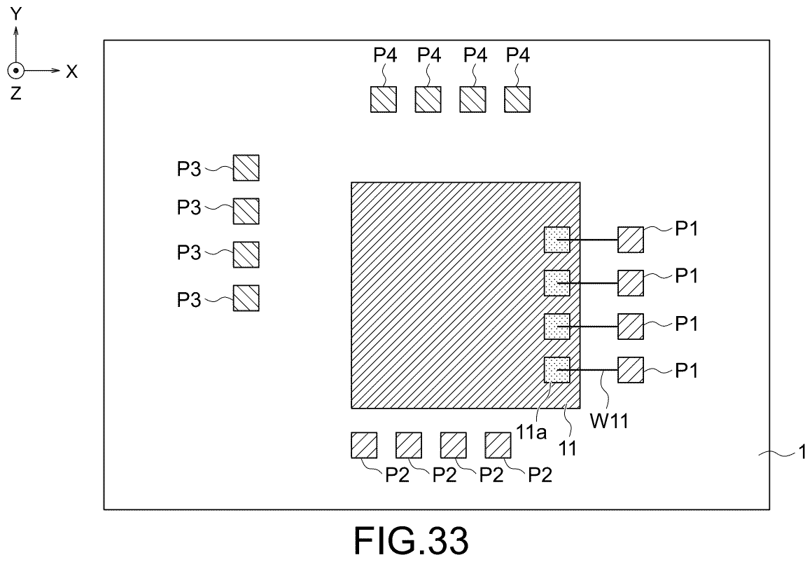

FIGS. 31 and 32 are a cross-sectional view and a plan view, respectively, illustrating the structure of a semiconductor device of the variant example of the first embodiment. FIGS. 33 to 35 are plan views illustrating a method of manufacturing the semiconductor device of the variant example of the first embodiment. FIGS. 31 to 35 correspond to FIGS. 1 to 5, respectively.

Similar to the semiconductor device of the first embodiment, the semiconductor device of this variant example includes a substrate 1, a resin layer 2, a plurality of metal pads P1, a plurality of metal pads P2, a plurality of metal pads P3, and a plurality of metal pads P4 (FIGS. 31 and 32).

Similar to the semiconductor device of the first embodiment, the semiconductor device of this variant example further includes a semiconductor chip 11 electrically connected to the metal pads P1, a semiconductor chip 21 electrically connected to the metal pads P2, a semiconductor chip 31 electrically connected to the metal pads P3, and a semiconductor chip 41 electrically connected to the metal pads P4 (FIGS. 31 and 32). These four semiconductor chips 11-41, however, are located in the −X direction from the metal pads P1, in the +Y direction from the metal pads P2, in the +X direction from the metal pads P3, and in the −Y direction from the metal pads P4. The −X direction in this variant example is an example of a first direction and the +Y direction in this variant example is an example of a second direction. The +X direction in this variant example is an example of a third direction and the −Y direction in this variant example is an example of a fourth direction.

The semiconductor device of this variant example may further include a control chip 51, similar to the semiconductor device of the fourth embodiment.

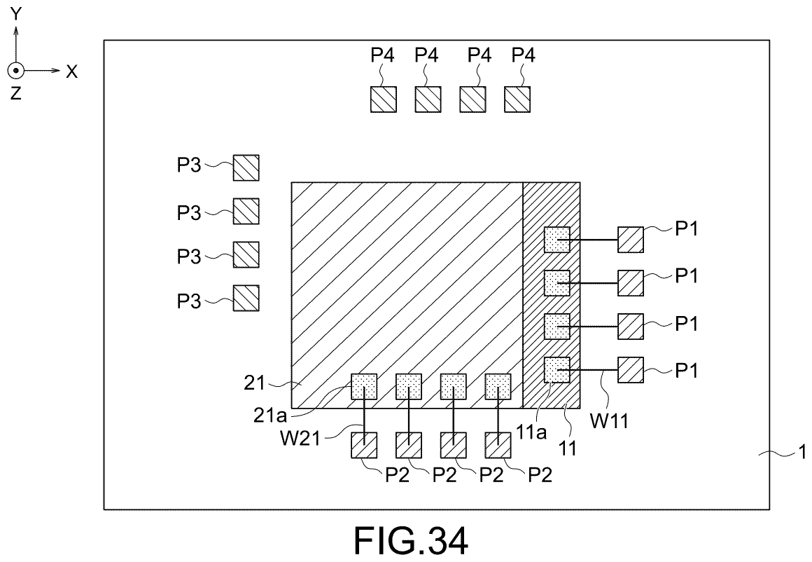

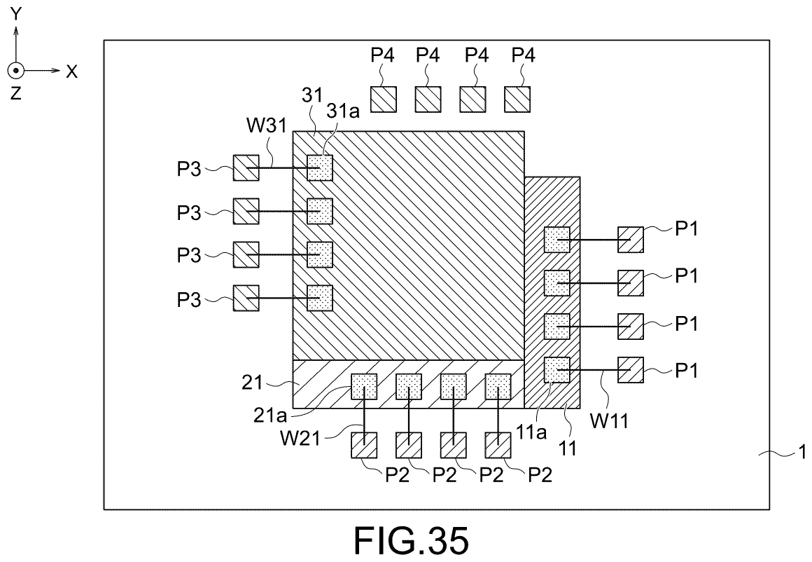

The semiconductor device of this variant example is manufactured by arranging the semiconductor chips 11-41 on the substrate 1. First, the metal pads P1-P4 are formed on the top surface of the substrate 1, and the semiconductor chip 11 is located on the substrate 1 (FIG. 33). Next, the semiconductor chip 21 is located on the semiconductor chip 11 (FIG. 34). Then, the semiconductor chip 31 is located on the semiconductor chip 21 (FIG. 35). After that, the semiconductor chip 41 is located on the semiconductor chip 31, and the resin layer 2 is formed on the substrate 1 (FIGS. 31 and 32).

In the following, the structure of the semiconductor device of this variant example will be described with reference to FIGS. 31 to 35.

### [Metal Pads P1-P4]

The metal pads P1-P4 are arranged around the semiconductor chips 11-41 on the substrate 1, as shown in FIG. 32. Specifically, the metal pads P1 are located in the +X direction from the semiconductor chips 11-41 and are arranged in line along the Y direction. The metal pads P2 are located in the −Y direction from the semiconductor chips 11-41 and are arranged in line along the X direction. The metal pads P3 are located in the −X direction from the semiconductor chips 11-41 and are arranged in line along the Y direction. The metal pads P4 are located in the +Y direction from the semiconductor chips 11-41 and are arranged in line along the X direction.

In this variant example, the semiconductor chips 11-41 have congruent shapes in planar view. Specifically, the shapes of the semiconductor chips 11-41 are congruent squares in planar view. The semiconductor chips 11-41 in this variant example have the same thickness (FIG. 31). In this variant example, the thicknesses of the semiconductor chips 11-41 are set to 50 μm or less (e.g., 20-50 μm). Note that the shapes and thicknesses of the semiconductor chips 11-41 may be different from those in this variant example.

### [Semiconductor Chip 11]

The semiconductor chip 11 is located in the −X direction from the metal pads P1 and is electrically connected to the metal pads P1 (FIG. 33). The (square) top surface of the semiconductor chip 11 has two sides parallel to the X direction and two sides parallel to the Y direction.

The semiconductor chip 11 has a plurality of metal pads 11a provided on the top surface of the semiconductor chip 11 (FIG. 33). These metal pads 11a are electrically connected to the metal pads P1 by a plurality of bonding wires W11. The metal pads 11a in this variant example are an example of one or more first chip pads.

### [Semiconductor Chip 21]

The semiconductor chip 21 is located in the +Y direction from the metal pads P2 and is electrically connected to the metal pads P2 (FIG. 34). The (square) top surface of the semiconductor chip 21 has two sides parallel to the X direction and two sides parallel to the Y direction. The semiconductor chip 21 is located on the semiconductor chip 11, not at a position where it completely overlaps with the semiconductor chip 11, but at a position where it partially overlaps with the semiconductor chip 11 in planar view. Specifically, the center of gravity of the top surface of the semiconductor chip 21 is located in the −X direction from the center of gravity of the top surface of the semiconductor chip 11. Thus, the semiconductor chips 11 and 21 are stacked on the substrate 1 to form stairsteps in the −X direction.

The semiconductor chip 21 has a plurality of metal pads 21a provided on the top surface of the semiconductor chip 21 (FIG. 34). These metal pads 21a are electrically connected to the metal pads P2 by a plurality of bonding wires W21. The metal pads 21a in this variant example are an example of one or more second chip pads.

Each of the metal pads 21a in this variant example is located at a position where it overlaps with the semiconductor chip 11 in planar view. This variant example makes it possible to reduce the possibility of cracking of the semiconductor chip 21 even when the semiconductor chip 21 is thin by virtue of the presence of the semiconductor chip 11 in the −Z direction from the metal pads 21a. FIG. 31 shows the metal pads 21a located at a position where they overlap with the semiconductor chip 11 in planar view.

### [Semiconductor Chip 31]

The semiconductor chip 31 is located in the +X direction from the metal pads P3 and is electrically connected to the metal pads P3 (FIG. 35). The (square) top surface of the semiconductor chip 31 has two sides parallel to the X direction and two sides parallel to the Y direction. The semiconductor chip 31 is located on the semiconductor chip 21, not at a position where it completely overlaps with the semiconductor chip 21, but at a position where it partially overlaps with the semiconductor chip 21 in planar view. Specifically, the center of gravity of the top surface of the semiconductor chip 31 is located in the +Y direction from the center of gravity of the top surface of the semiconductor chip 21. Thus, the semiconductor chips 21 and 31 are stacked on the semiconductor chip 11 to form stairsteps in the +Y direction.

The semiconductor chip 31 has a plurality of metal pads 31a provided on the top surface of the semiconductor chip 31 (FIG. 35). These metal pads 31a are electrically connected to the metal pads P3 by a plurality of bonding wires W31. The metal pads 31a in this variant example are an example of one or more third chip pads.

Each of the metal pads 31a in this variant example is located at a position where it overlaps with the semiconductor chip 21 in planar view. This variant example makes it possible to reduce the possibility of cracking of the semiconductor chip 31 even when the semiconductor chip 31 is thin by virtue of the presence of the semiconductor chip 21 in the −Z direction from the metal pads 31a. FIG. 31 shows the metal pads 31a located at a position where they overlap with the semiconductor chip 21 in planar view.

### [Semiconductor Chip 41]

The semiconductor chip 41 is located in the −Y direction from the metal pads P4 and is electrically connected to the metal pads P4 (FIG. 32). The (square) top surface of the semiconductor chip 41 has two sides parallel to the X direction and two sides parallel to the Y direction. The semiconductor chip 41 is located on the semiconductor chip 31, not at a position where it completely overlaps with the semiconductor chip 31, but at a position where it partially overlaps with the semiconductor chip 31 in planar view. Specifically, the center of gravity of the top surface of the semiconductor chip 41 is located in the +X direction from the center of gravity of the top surface of the semiconductor chip 31. Thus, the semiconductor chips 31 and 41 are stacked on the semiconductor chip 21 to form stairsteps in the +X direction.

The semiconductor chip 41 has a plurality of metal pads 41a provided on the top surface of the semiconductor chip 41 (FIG. 32). These metal pads 41a are electrically connected to the metal pads P4 by a plurality of bonding wires W41. The metal pads 41a in this variant example are an example of one or more fourth chip pads.

Each of the metal pads 41a in this variant example is located at a position where it overlaps with the semiconductor chip 31 in planar view. This variant example makes it possible to reduce the possibility of cracking of the semiconductor chip 41 even when the semiconductor chip 41 is thin by virtue of the presence of the semiconductor chip 31 in the −Z direction from the metal pads 41a. FIG. 31 shows the metal pads 41a located at a position where they overlap with the semiconductor chip 31 in planar view.

In this variant example, the semiconductor chips 11 and 21 form stairsteps extending in the −X direction, and the semiconductor chips 21 and 31 form stairsteps extending in the +Y direction. As a result, the direction in which the stairsteps of the semiconductor chips 21 and 31 extend (+Y direction) is rotated 90 degrees clockwise with respect to the direction in which the stairsteps of the semiconductor chips 11 and 21 extend (−X direction) in planar view. Likewise, the direction in which the stairsteps of the semiconductor chips 31 and 41 extend (+X direction) is rotated 90 degrees clockwise with respect to the direction in which the stairsteps of the semiconductor chips 21 and 31 extend (+Y direction) in planar view. In this way, these semiconductor chips 11-41 are arranged in a spiral extending in the Z direction. Clockwise rotation is an example of a predetermined rotational direction.

As described above, in this variant example, the metal pads 21a are located at a position where they overlap with the semiconductor chip 11, the metal pads 31a are located at a position where they overlap with the semiconductor chip 21, and the metal pads 41a are located at a position where they overlap with the semiconductor chip 31. Consequently, this variant example makes it possible to reduce the possibility of cracking of the semiconductor chips 21-41 when the bonding wires W21-W41 are bonded to the metal pads 21a-41a, and therefore to stack the semiconductor chips 11-41 suitably.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the devices described herein may be made without departing from the spirit of the inventions. The accompanying claims and their equivalents are intended to cover such forms or modifications as would fall within the scope and spirit of the inventions.

1. A semiconductor device comprising:
a substrate;
one or more first substrate pads provided on the substrate;
one or more first chips provided on the substrate and located in a first direction from the first substrate pads, each of the first chips including one or more first chip pads electrically connected to the first substrate pads;
one or more second substrate pads provided on the substrate; and
one or more second chips provided on the first chips and located in a second direction from the second substrate pads, the second direction intersecting the first direction, each of the second chips including one or more second chip pads electrically connected to the second substrate pads,
wherein each of the second chip pads is located to overlap with a highest first chip of the first chips in planar view.

2. The device of claim 1, further comprising:
one or more third substrate pads provided on the substrate; and
one or more third chips provided on the second chips and located in a third direction from the third substrate pads, the third direction intersecting the second direction, each of the third chips including one or more third chip pads electrically connected to the third substrate pads,
wherein each of the third chip pads is located to overlap with a highest second chip of the second chips in planar view.

3. The device of claim 2, further comprising:
one or more fourth substrate pads provided on the substrate; and
one or more fourth chips provided on the third chips and located in a fourth direction from the fourth substrate pads, the fourth direction intersecting the third direction, each of the fourth chips including one or more fourth chip pads electrically connected to the fourth substrate pads,
wherein each of the fourth chip pads is located to overlap with a highest third chip of the third chips in planar view.

4. The device of claim 1, further comprising:
one or more third chips provided on the second chips and located in the first direction from the first substrate pads, each of the third chips including one or more third chip pads electrically connected to the first substrate pads,
wherein each of the third chip pads is located to overlap with a highest second chip of the second chips in planar view.

5. The device of claim 4, further comprising:
one or more fourth chips provided on the third chips and located in the second direction from the second substrate pads, each of the fourth chips including one or more fourth chip pads electrically connected to the second substrate pads,
wherein each of the fourth chip pads is located to overlap a highest third chip of the third chips in planar view.

6. The device of claim 1, wherein
the first chips include a plurality of first chips stacked to form stairsteps in the first direction, and
the second chips include a plurality of second chips stacked to form stairsteps in the second direction.

7. The device of claim 6, wherein
the plurality of first chips are stacked to form the stairsteps only in the first direction, and
the plurality of second chips are stacked to form the stairsteps in the second direction and in the first direction.

8. The device of claim 2, wherein
the first chips include a plurality of first chips stacked to form stairsteps in the first direction,
the second chips include a plurality of second chips stacked to form stairsteps in the second direction, and
the third chips include a plurality of third chips stacked to form stairsteps in the third direction.

9. The device of claim 8, wherein
the plurality of first chips are stacked to form the stairsteps only in the first direction,
the plurality of second chips are stacked to form the stairsteps in the second direction and in the first direction, and
the plurality of third chips are stacked to form the stairsteps in the third direction and in the second direction.

10. The device of claim 3, wherein
the first chips include a plurality of first chips stacked to form stairsteps in the first direction,
the second chips include a plurality of second chips stacked to form stairsteps in the second direction,
the third chips include a plurality of third chips stacked to form stairsteps in the third direction, and
the fourth chips include a plurality of fourth chips stacked to form stairsteps in the fourth direction.

11. The device of claim 3, wherein
the second direction is rotated 90 degrees in a predetermined rotational direction with respect to the first direction,
the third direction is rotated 90 degrees in the predetermined rotational direction with respect to the second direction, and
the fourth direction is rotated 90 degrees in the predetermined rotational direction with respect to the third direction.

12. The device of claim 3, wherein the first chips, the second chips, the third chips, and the fourth chips are arranged in a spiral.

13. The device of claim 1, wherein when
a length of short sides of the second chips is denoted as “a” [mm],
a length of long sides of the second chips is denoted as “b” [mm], and
a distance between a center line of the second chips parallel to the second direction and an outermost second chip pad of the second chip pads is denoted as “e” [mm],
e≤b−a/2−0.3 holds.

14. The device of claim 2, wherein when
a length of short sides of the third chips is denoted as “a” [mm],
a length of long sides of the third chips is denoted as “b” [mm], and
a distance between a center line of the third chips parallel to the third direction and an outermost third chip pad of the third chip pads is denoted as “e” [mm],
e≤b−a/2−0.3 holds.

15. The device of claim 3, wherein when
a length of short sides of the fourth chips is denoted as “a” [mm],
a length of long sides of the fourth chips is denoted as “b” [mm], and
a distance between a center line of the fourth chips parallel to the fourth direction and an outermost fourth chip pad of the fourth chip pads is denoted as “e” [mm],
e≤b−a/2−0.3 holds.

16. The device of claim 5, further comprising a control chip including a portion provided under the fourth chips in planar view.

17. The device of claim 1, wherein a thickness of a lowest first chip of the first chips is thicker than thicknesses of other first chips of the first chips.

18. A semiconductor device comprising:
a substrate;
a plurality of first substrate pads provided on the substrate;
a plurality of first chips provided on the substrate and located in a first direction from the first substrate pads, the first chips being stacked to form stairsteps in the first direction and electrically connected to the first substrate pads;
a plurality of second substrate pads provided on the substrate; and
a plurality of second chips provided on the first chips and located in a second direction from the second substrate pads, the second direction intersecting the first direction, the second chips being stacked to form stairsteps in the second direction and electrically connected to the second substrate pads.

19. The device of claim 18, further comprising:
a plurality of third substrate pads provided on the substrate; and
a plurality of third chips provided on the second chips and located in a third direction from the third substrate pads, the third direction intersecting the second direction, the third chips being stacked to form stairsteps in the third direction and electrically connected to the third substrate pads.

20. The device of claim 19, further comprising:
a plurality of fourth substrate pads provided on the substrate; and
a plurality of fourth chips provided on the third chips and located in a fourth direction from the fourth substrate pads, the fourth direction intersecting the third direction, the fourth chips being stacked to form stairsteps in the fourth direction and electrically connected to the fourth substrate pads.
